(19) United States
(12) Patent Application Publication
(10) Pub. No.: US 2026/0162711 A1
(43) Pub. Date: Jun. 11, 2026

(54) SEMICONDUCTOR MEMORY DEVICE AND MEMORY SYSTEM INCLUDING THE SAME

(71) Applicant: Samsung Electronics Co., Ltd., Suwon-si (KR)

(72) Inventors: Yoonjae Kim, Suwon-si (KR); Jinwoo Han, Suwon-si (KR)

(21) Appl. No.: 19/317,028

(22) Filed: Sep. 2, 2025

(30) Foreign Application Priority Data
Dec. 11, 2024 (KR) 10-2024-0183405

(51) Int. Cl. G11C 11/4097; G11C 11/4094

(52) U.S. Cl. CPC G11C 11/4097; G11C 11/4094

(57) ABSTRACT

A semiconductor memory device includes memory cells, local bitlines, global bitlines, wordlines, control lines, local bitline multiplexers, and first and second control contacts. The memory cells are arranged along first, second and third directions. Each local bitline extends in the first direction, and is shared by memory cells adjacent to a first side and a second side of each local bitline. The global bitlines are disposed on the local bitlines. The control lines are disposed on the wordlines. Each wordline and each control line extend in the third direction. The local bitline multiplexers control electrical connections between the local bitlines and the global bitlines. At least two of the local bitline multiplexers share one of the control lines. The first and second control contacts are respectively connected to first ends and second ends of the control lines. Each of the first and second control contacts extends in the first direction.

### CROSS-REFERENCE TO RELATED APPLICATION(S)

This application claims priority under 35 USC § 119 to Korean Patent Application No. 10-2024-0183405 filed on Dec. 11, 2024 in the Korean Intellectual Property Office (KIPO), the disclosure of which is herein incorporated by reference in its entirety.

### BACKGROUND

### 1. Technical Field

Example embodiments relate generally to semiconductor integrated circuits, and more particularly to three-dimensional (3D) semiconductor memory devices and memory systems including the 3D semiconductor memory devices.

### 2. Description of the Related Art

The demand/desire for the miniaturization, multi-function and/or high-performance of electronic products causes the demand for high-capacity semiconductor memory devices. To provide the high-capacity semiconductor memory devices, an increased degree of integration is demanded/desired. Since a degree of integration of existing two-dimensional (2D) semiconductor memory devices may mainly be determined by an area occupied by a unit memory cell, the degree of integration of 2D semiconductor memory devices has been increasing, but is still limited. Therefore, three-dimensional (3D) semiconductor memory devices have been proposed to increase a memory capacity by stacking a plurality of memory cells on a substrate in a vertical direction.

### SUMMARY

Various example embodiments of the present disclosure provide a semiconductor memory device capable of having improved electrical characteristics and reliability.

Various example embodiments of the present disclosure provide a memory system including the semiconductor memory device.

According to example embodiments, a semiconductor memory device includes a plurality of memory cells, a plurality of local bitlines, a plurality of global bitlines, a plurality of wordlines, a plurality of control lines, a plurality of local bitline multiplexers, a plurality of first control contacts and a plurality of second control contacts. The plurality of memory cells are disposed on a substrate, and are arranged along a first direction, a second direction and a third direction. The first direction is perpendicular to an upper surface of the substrate. The second and third directions are parallel to the upper surface of the substrate and intersecting each other. The plurality of local bitlines are disposed on the substrate, and are connected to the plurality of memory cells. Each of the plurality of local bitlines extends in the first direction, and is shared by memory cells adjacent to a first side of each of the plurality of local bitlines and memory cells adjacent to a second side of each of the plurality of local bitlines. The plurality of global bitlines are disposed on the plurality of local bitlines. The plurality of wordlines are disposed on the substrate, and are connected to the plurality of memory cells. Each of the plurality of wordlines extends in the third direction. The plurality of control lines are disposed on the plurality of wordlines. Each of the plurality of control lines extends in the third direction. The plurality of local bitline multiplexers control electrical connections between the plurality of local bitlines and the plurality of global bitlines. At least two of the plurality of local bitline multiplexers share one of the plurality of control lines. The plurality of first control contacts are connected to first ends of the plurality of control lines. Each of the plurality of first control contacts extends in the first direction. The plurality of second control contacts are connected to second ends of the plurality of control lines. Each of the plurality of second control contacts extends in the first direction.

According to example embodiments, a semiconductor memory device includes local bitlines, first memory cells, second memory cells, first wordlines, second wordlines, global bitlines, a first control line, selection transistors, a first control contact and a second control contact. The local bitlines are disposed on a substrate. Each of the local bitlines extends in a first direction perpendicular to an upper surface of the substrate. The local bitlines are spaced apart from each other in a third direction among a second direction and the third direction. The second and third directions are parallel to the upper surface of the substrate and intersecting each other. The first memory cells are disposed on the substrate, are connected to the local bitlines, and are arranged along the first and third directions to be adjacent to first sides of the local bitlines. The second memory cells are disposed on the substrate, are connected to the local bitlines, and are arranged along the first and third directions to be adjacent to second sides of the local bitlines. The first wordlines are disposed on the substrate, and are arranged along the first direction. Each of the first wordlines extends in the third direction, and is connected to memory cells at the same level among the first memory cells. The second wordlines are disposed on the substrate, and are arranged along the first direction. Each of the second wordlines extends in the third direction, and is connected to memory cells at the same level among the second memory cells. Each of the global bitlines is selectively connected to one of the local bitlines. The first control line is disposed on the first wordlines, and extends in the third direction. The selection transistors control electrical connections between the local bitlines and the global bitlines. The first control line is shared by the selection transistors. The first and second control contacts are connected to a first end and a second end of the first control line, respectively. Each of the first and second control contacts extends in the first direction.

According to example embodiments, a memory system includes a memory controller and a semiconductor memory device configured to be controlled by the memory controller. The semiconductor memory device includes a plurality of memory cells, a plurality of local bitlines, a plurality of global bitlines, a plurality of wordlines, a plurality of control lines, a plurality of local bitline multiplexers, a plurality of first control contacts and a plurality of second control contacts. The plurality of memory cells are disposed on a substrate, and are arranged along a first direction, a second direction and a third direction. The first direction is perpendicular to an upper surface of the substrate. The second and third directions are parallel to the upper surface of the substrate and intersecting each other. The plurality of local bitlines are disposed on the substrate, and are connected to the plurality of memory cells. Each of the plurality of local bitlines extends in the first direction, and is shared by memory cells adjacent to a first side of each of the plurality of local bitlines and memory cells adjacent to a second side of each of the plurality of local bitlines. The plurality of global bitlines are disposed on the plurality of local bitlines. The plurality of wordlines are disposed on the substrate, and are connected to the plurality of memory cells. Each of the plurality of wordlines extends in the third direction. The plurality of control lines are disposed on the plurality of wordlines. Each of the plurality of control lines extends in the third direction. The plurality of local bitline multiplexers control electrical connections between the plurality of local bitlines and the plurality of global bitlines. At least two of the plurality of local bitline multiplexers share one of the plurality of control lines. The plurality of first control contacts are connected to first ends of the plurality of control lines. Each of the plurality of first control contacts extends in the first direction. The plurality of second control contacts are connected to second ends of the plurality of control lines. Each of the plurality of second control contacts extends in the first direction.

In the semiconductor memory device and the memory system according to example embodiments, adjacent memory cells may share the local bitline. In addition, the local bitline multiplexer that controls the electrical connection between the local bitline and the global bitline may be disposed on each local bitline, and the structures at the uppermost level of the memory cell array may be used as the local bitline multiplexer. Further, two control contacts for signal application may be disposed at both ends of the control line that is connected to the local bitline multiplexer. Accordingly, the semiconductor memory device may have improved electrical characteristics and improved reliability.

For example, the local bitline and the global bitline may be selectively connected and disconnected using the local bitline multiplexer, and thus the capacitance of the bitline may be reduced and the sensing margin may increase. In addition, the signal for turning on and off of the local bitline multiplexer may be applied to the control line using two control contacts, the delay time when the local bitline multiplexer is turned on/off may be reduced and the operating performance may be improved.

### BRIEF DESCRIPTION OF THE DRAWINGS

Illustrative, non-limiting example embodiments will be more clearly understood from the following detailed description taken in conjunction with the accompanying drawings.

FIG. 1 is a perspective view of a semiconductor memory device according to example embodiments.

FIG. 2 is a circuit diagram illustrating the semiconductor memory device of FIG. 1 according to example embodiments.

FIGS. 3 and 4 are a perspective view and a plan view for describing a semiconductor memory device according to example embodiments.

FIGS. 5, 6, 7 and 8 are cross-sectional views for describing the semiconductor memory device of FIGS. 3 and 4 according to example embodiments.

FIGS. 9A and 9B are diagrams for describing an operation of a semiconductor memory device according to example embodiments.

FIGS. 10 and 11 are cross-sectional views for describing the semiconductor memory device of FIGS. 3 and 4 according to example embodiments.

FIGS. 12, 13, 14 and 15 are perspective views and plan views for describing a semiconductor memory device according to example embodiments.

FIG. 16 is a perspective view of a semiconductor memory device according to example embodiments.

FIGS. 17 and 18 are a perspective view and a cross-sectional view of a semiconductor memory device according to example embodiments.

FIG. 19 is a circuit diagram illustrating the semiconductor memory device of FIGS. 16 and 17 according to example embodiments.

FIG. 20 is a block diagram illustrating a semiconductor memory device according to example embodiments.

FIG. 21 is a block diagram illustrating a memory system according to example embodiments.

### DETAILED DESCRIPTION OF THE EMBODIMENTS

Various example embodiments will be described more fully with reference to the accompanying drawings, in which embodiments are shown. The present disclosure may, however, be embodied in many different forms and should not be construed as limited to the embodiments set forth herein. Like reference numerals refer to like elements throughout this application.

Hereinafter, in the specification (and not necessarily in the claims), a vertical direction that is perpendicular to an upper surface of a substrate may be referred to as a first direction D1, and two intersecting directions among horizontal directions that are parallel to the upper surface of the substrate may be referred to as second and third directions D2 and D3, respectively. For example, the second and third directions D2 and D3 may be perpendicular to each other. Each of the first, second and third directions D1, D2 and D3 may include not only a direction shown in the drawings but also a direction inverse thereto.

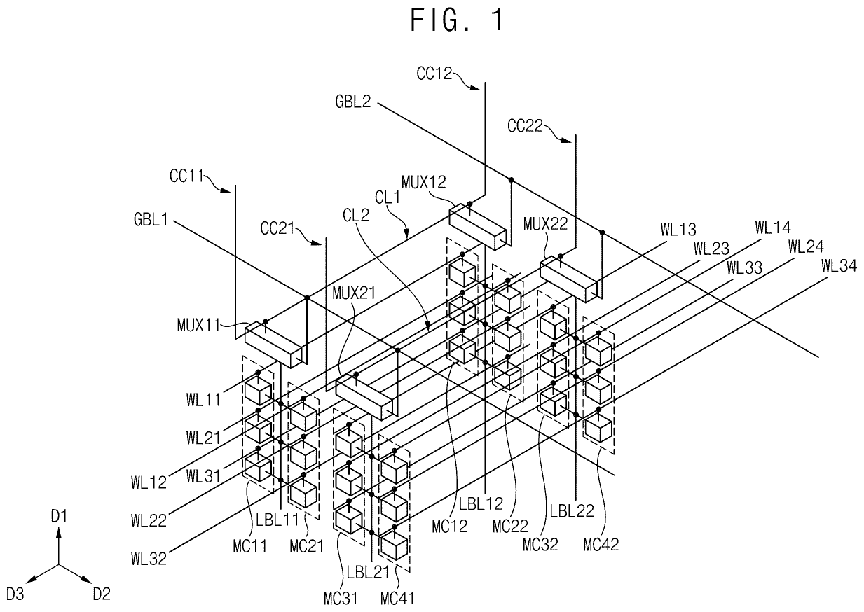

FIG. 1 is a perspective view of a semiconductor memory device according to example embodiments.

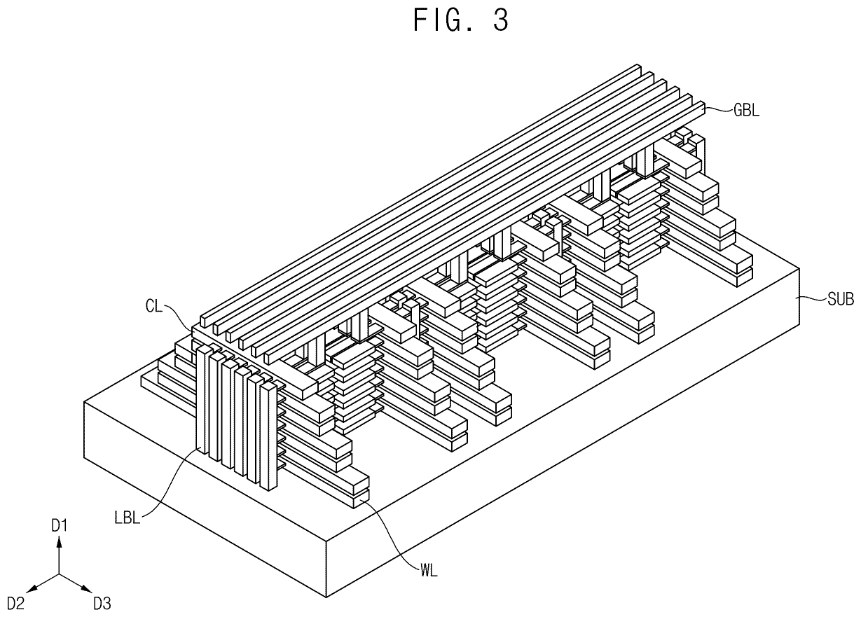

Referring to FIG. 1, a portion of a memory cell array of a semiconductor memory device is illustrated. For example, the memory cell array (or the portion thereof) may be formed, disposed and/or arranged on the substrate (e.g., a substrate SUB in FIG. 3).

The semiconductor memory device includes a plurality of memory cells MC11, MC21, MC31, MC41, MC12, MC22, MC32 and MC42, a plurality of local bitlines LBL11, LBL21, LBL12 and LBL22, a plurality of global bitlines GBL1 and GBL2, a plurality of wordlines WL11, WL21, WL31, WL12, WL22, WL32, WL13, WL23, WL33, WL14, WL24 and WL34, a plurality of control lines CL1 and CL2, a plurality of local bitline multiplexers MUX11, MUX21, MUX12 and MUX22, a plurality of first control contacts CC11 and CC21, and a plurality of second control contacts CC12 and CC22.

The plurality of memory cells MC11, MC21, MC31, MC41, MC12, MC22, MC32 and MC42 are disposed on the substrate, and are arranged along the first, second and third directions D1, D2 and D3. Unlike a two-dimensional (2D) semiconductor memory device in which memory cells are arranged only along the second and third directions D2 and D3, the semiconductor memory device according to example embodiments may be a three-dimensional (3D) semiconductor memory device in which the plurality of memory cells MC11, MC21, MC31, MC41, MC12, MC22, MC32 and MC42 are arranged not only along the second and third directions D2 and D3 but also along the first direction D1.

The plurality of local bitlines LBL11, LBL21, LBL12 and LBL22 are disposed on the substrate, and are electrically connected to the plurality of memory cells MC11, MC21, MC31, MC41, MC12, MC22, MC32 and MC42. Each of the plurality of local bitlines LBL11, LBL21, LBL12 and LBL22 extends in the first direction D1. The plurality of local bitlines LBL11, LBL21, LBL12 and LBL22 may be spaced apart from each other in the second and third directions D2 and D3.

In some example embodiments, some memory cells may be disposed between two local bitlines that are arranged adjacently along the second direction D2. Memory cells that are arranged adjacently along the first direction D1 in which each local bitline extends may be electrically connected to the same local bitline. For example, memory cells that are arranged along the first direction D1 may form one cell string, and each cell string and the memory cells included therein may be electrically connected to one local bitline. In some example embodiments, some memory cells that are arranged adjacently along the second direction D2 may be electrically connected to the same local bitline. For example, two cell strings, which are arranged adjacent to a first side and a second side of one local bitline and along the second direction D2, and memory cells included therein may be electrically connected to the one local bitline and may share the one local bitline.

For example, the memory cells MC21 and MC31 may be disposed between the local bitlines LBL11 and LBL21 that are adjacent to each other in the second direction D2. Although not illustrated in FIG. 1, the memory cells MC11 and other memory cells (not shown) may be disposed between the local bitline LBL11 and another local bitline (not shown) adjacent to the local bitline LBL11 in the second direction D2, and the memory cells MC41 and other memory cells (not shown) may be disposed between the local bitline LBL21 and another local bitline (not shown) adjacent to the local bitline LBL21 in the second direction D2.

For example, the memory cells MC11 and MC21 may be adjacent to each other in the second direction D2, and may share the local bitline LBL11. For example, the memory cells MC11 that are arranged along the first direction D1 may be adjacent to a first side (e.g., the left side) of the local bitline LBL11, and may be electrically connected to the same local bitline (e.g., the local bitline LBL11). For example, the memory cells MC21 that are arranged along the first direction D1 may be adjacent to a second side (e.g., the right side) of the local bitline LBL11, and may be electrically connected to the same local bitline (e.g., the local bitline LBL11).

For example, the memory cells MC31 and MC41 may be adjacent to each other in the second direction D2, and may share the local bitline LBL21. For example, the memory cells MC31 that are arranged along the first direction D1 may be adjacent to a first side of the local bitline LBL21, and may be electrically connected to the same local bitline (e.g., the local bitline LBL21). For example, the memory cells MC41 that are arranged along the first direction D1 may be adjacent to a second side of the local bitline LBL21, and may be electrically connected to the same local bitline (e.g., the local bitline LBL21).

Similarly, the memory cells MC12 and the memory cells MC22 may be adjacent to a first side and a second side of the local bitline LBL12, respectively, may be electrically connected to the local bitline LBL12, and may share the local bitline LBL12. The memory cells MC32 and the memory cells MC42 may be arranged adjacent to a first side and a second side of the local bitline LBL22, respectively, may be electrically connected to the local bitline LBL22, and may share the local bitline LBL22.

As described above, one local bitline may be shared by adjacent memory cells, and thus the semiconductor memory device may have the increased degree of integration and improved characteristics.

The plurality of global bitlines GBL1 and GBL2 are disposed on the plurality of local bitlines LBL11, LBL21, LBL12 and LBL22. For example, each of the plurality of global bitlines GBL1 and GBL2 may extend in the second direction D2.

Each of the plurality of global bitlines GBL1 and GBL2 is selectively electrically connected to one of the plurality of local bitlines LBL11, LBL21, LBL12 and LBL22. For example, the global bitline GBL1 may be selectively electrically connected to one of the local bitlines LBL11 and LBL21, and the global bitline GBL2 may be selectively electrically connected to one of the local bitlines LBL12 and LBL22.

The plurality of wordlines WL11, WL21, WL31, WL12, WL22, WL32, WL13, WL23, WL33, WL14, WL24 and WL34 are disposed on the substrate, and are electrically connected to the plurality of memory cells MC11, MC21, MC31, MC41, MC12, MC22, MC32 and MC42. Each of the plurality of wordlines WL11, WL21, WL31, WL12, WL22, WL32, WL13, WL23, WL33, WL14, WL24 and WL34 extends in the third direction D3. The plurality of wordlines WL11, WL21, WL31, WL12, WL22, WL32, WL13, WL23, WL33, WL14, WL24 and WL34 may be spaced apart from each other in the first and second directions D1 and D2.

In some example embodiments, memory cells that are arranged at the same level and arranged adjacently along the third direction D3 along which each wordline extends may be electrically connected to the same wordline. For example, memory cells that are arranged along the third direction D3 at the same level may form one cell column, and each cell column and the memory cells included therein may be electrically connected to one wordline.

For example, among the memory cells MC11 and the memory cells MC12 that are adjacent to each other in the third direction D3, memory cells at the same level may be electrically connected to the same wordline among the wordlines WL11, WL21 and WL31. For example, among the memory cells MC11 and MC12, memory cells at the uppermost level may be electrically connected to the wordline WL11, memory cells at the middle level may be electrically connected to the wordline WL21, and memory cells at the lowermost level may be electrically connected to the wordline WL31.

For example, among the memory cells MC21 and the memory cells MC22 that are adjacent to each other in the third direction D3, memory cells at the same level may be electrically connected to the same wordline among the wordlines WL12, WL22 and WL32. For example, among the memory cells MC21 and MC12, memory cells at the uppermost level may be electrically connected to the wordline WL12, memory cells at the middle level may be electrically connected to the wordline WL22, memory cells at the lowermost level may be electrically connected to the wordline WL32.

Similarly, among the memory cells MC31 and the memory cells MC32 that are adjacent to each other in the third direction D3, memory cells at the same level may be electrically connected to the same wordline among the wordlines WL13, WL23 and WL33. Among the memory cells MC41 and the memory cells MC42 that are adjacent to each other in the third direction D3, memory cells at the same level may be electrically connected to the same wordline among the wordlines WL14, WL24 and WL34.

The plurality of control lines CL1 and CL2 are disposed on the plurality of wordlines WL11, WL21, WL31, WL12, WL22, WL32, WL13, WL23, WL33, WL14, WL24 and WL34. Each of the plurality of control lines CL1 and CL2 extends in the third direction D3. For example, each of the plurality of control lines CL1 and CL2 may be connected to at least one of the plurality of local bitline multiplexers MUX11, MUX21, MUX12 and MUX22.

The plurality of local bitline multiplexers MUX11, MUX21, MUX12 and MUX22 control electrical connections between the plurality of local bitlines LBL11, LBL21, LBL12 and LBL22 and the plurality of global bitlines GBL1 and GBL2.

For example, the local bitline multiplexer MUX11 may control the electrical connection between the local bitline LBL11 and the global bitline GBL1, and the local bitline multiplexer MUX21 may control the electrical connection between the local bitline LBL21 and the global bitline GBL1. Similarly, the local bitline multiplexer MUX12 may control the electrical connection between the local bitline LBL12 and the global bitline GBL2, and the local bitline multiplexer MUX22 may control the electrical connection between the local bitline LBL22 and the global bitline GBL2. Although not shown, each of the local bitline multiplexers MUX11 and MUX21 may include a bit-line sense amplifier (BLSA) coupled to the local bitlines LBL11 and LBL21, respectively, and each of the local bitline multiplexers MUX12 and MUX22 may include a BLSA coupled to the local bitlines LBL12 and LBL22, respectively. For example, the BLSA may sense and amplify a voltage detected on the selected local bitline to provide the amplified voltage to the local bitline and/or the selected global bitline.

At least two of the plurality of local bitline multiplexers MUX11, MUX21, MUX12 and MUX22 share one of the plurality of control lines CL1 and CL2. For example, local bitline multiplexers that are arranged adjacently along the third direction D3 may be electrically connected to the same control line.

For example, the local bitline multiplexer MUX11 and the local bitline multiplexer MUX12 that are adjacent to each other in the third direction D3 may be electrically connected to the same control line (e.g., the control line CL1). Similarly, the local bitline multiplexer MUX21 and the local bitline multiplexer MUX22 that are adjacent to each other in the third direction D3 may be electrically connected to the same control line (e.g., the control line CL2). Although FIG. 1 illustrates that adjacent local bitline multiplexers share one control line, the present invention is not limited thereto, and three or more adjacent local bitline multiplexers may share one control line.

The plurality of first control contacts CC11 and CC21 are connected to first ends of the plurality of control lines CL1 and CL2. Each of the plurality of first control contacts CC11 and CC21 extends in the first direction D1. For example, the first control contact CC11 may be connected to the first end of the control line CL1, and the first control contact CC21 may be connected to the first end of the control line CL2.

The plurality of second control contacts CC12 and CC22 are connected to second ends of the plurality of control lines CL1 and CL2. Each of the plurality of second control contacts CC12 and CC22 extends in the first direction D1. For example, the second control contact CC12 may be connected to the second end of the control line CL1, and the second control contact CC22 may be connected to the second end of the control line CL2.

In some example embodiments, one first control contact and one second control contact may be connected to one control line. Thus, the number of the control lines CL1 and CL2, the number of the first control contacts CC11 and CC21, and the number of the second control contacts CC12 and CC22 may be the same as each other.

Although FIG. 1 illustrates an example of the semiconductor memory device that includes specific numbers of memory cells, local bitlines, global bitlines, wordlines, control lines, local bitline multiplexers and control contacts, the present invention is not limited thereto.

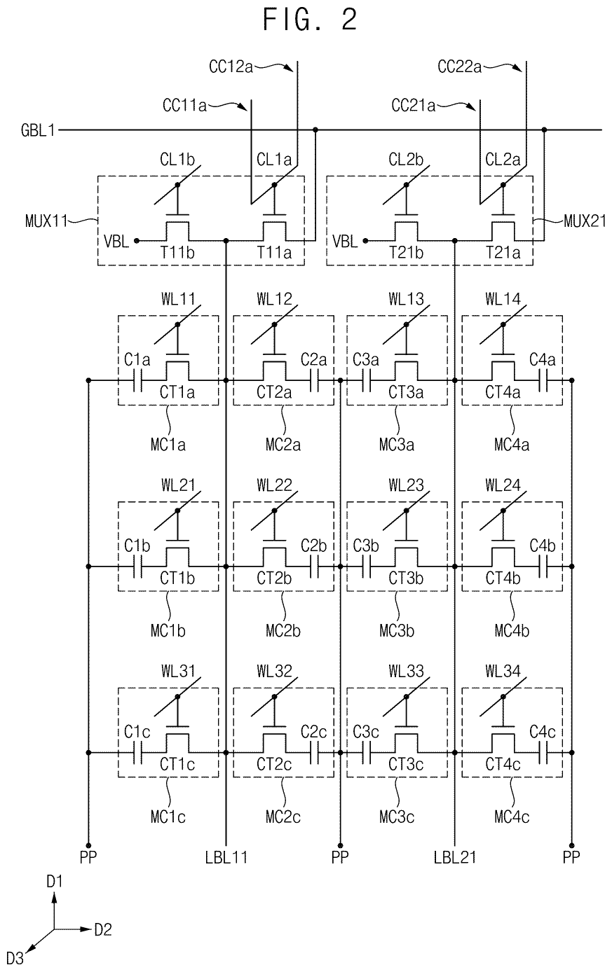

FIG. 2 is a circuit diagram illustrating the semiconductor memory device of FIG. 1 according to example embodiments.

Referring to FIG. 2, an example of components that are connected to the local bitlines LBL11 and LBL21 and the global bitline GBL1 in the semiconductor memory device of FIG. 1 is illustrated. The descriptions repeated with or overlapping with descriptions of FIG. 1 will be omitted in the interest of brevity.

Each of memory cells MC1a, MC1b, MC1c, MC2a, MC2b, MC2c, MC3a, MC3b, MC3c, MC4a, MC4b and MC4c may include one of the cell transistors CT1a, CT1b, CT1c, CT2a, CT2b, CT2c, CT3a, CT3b, CT3c, CT4a, CT4b and CT4c and one of the capacitors C1a, C1b, C1c, C2a, C2b, C2c, C3a, C3b, C3c, C4a, C4b and C4c, and may be connected to one of the local bitlines LBL11 and LBL21 and one of the wordlines WL11, WL21, WL31, WL12, WL22, WL32, WL13, WL23, WL33, WL14, WL24 and WL34. For example, the semiconductor memory device may be a dynamic random access memory (DRAM) device, and each memory cell may be a DRAM cell with a 1T-1C structure including one cell transistor and one capacitor.

Each of the cell transistors CT1a, CT1b, CT1c, CT2a, CT2b, CT2c, CT3a, CT3b, CT3c, CT4a, CT4b and CT4c may include a gate electrode that is connected to one of the wordlines WL11, WL21, WL31, WL12, WL22, WL32, WL13, WL23, WL33, WL14, WL24 and WL34, a first source/drain that is connected to one of the local bitlines LBL11 and LBL21, and a second source/drain that is connected to a first end of one of the capacitors C1a, C1b, C1c, C2a, C2b, C2c, C3a, C3b, C3c, C4a, C4b and C4c. The capacitors C1a, C1b, C1c, C2a, C2b, C2c, C3a, C3b, C3c, C4a, C4b and C4c may be commonly connected to a plate (or plate electrode) PP. For example, a second end of each of the capacitors C1a, C1b, C1c, C2a, C2b, C2c, C3a, C3b, C3c, C4a, C4b and C4c may be commonly connected to the plate PP.

For example, the memory cell MC1a may include the cell transistor CT1a and the capacitor C1a, the cell transistor CT1a may have a gate electrode connected to the wordline WL11 and may be connected between the local bitline LBL11 and the capacitor C1a, and the capacitor C1a may be connected between the cell transistor CT1a and the plate PP. Similarly, the memory cell MC1b may include the cell transistor CT1b and the capacitor C1b, and may be connected to the wordline WL21 and the local bitline LBL11. The memory cell MC1c may include the cell transistor CT1c and the capacitor C1c, and may be connected to the wordline WL31 and the local bitline LBL11. Although not shown, bit line selection transistors may be disposed between a bitline BL of each of the cell transistors CT1a, CT1b, CT1c, CT2a, CT2b, and CT2c and the local bitlines LBL11. For example, when one of the cell transistors CT1a, CT1b, CT1c, CT2a, CT2b, and CT2c is selected by a selected wordline, a selected bitline may be electrically connected to the local bitlines LBL11 through a selected bit line selection transistor. The memory cells MC1a, MC1b and MC1c may correspond to the memory cells MC11 in FIG. 1.

Similarly, each of the memory cells MC2a, MC2b and MC2c may include one of the cell transistors CT2a, CT2b and CT2c and one of the capacitors C2a, C2b and C2c, may be connected to one of the wordlines WL12, WL22 and WL32 and the local bitline LBL11, and may correspond to the memory cells MC21 in FIG. 1. Each of the memory cells MC3a, MC3b and MC3c may include one of the cell transistors CT3a, CT3b and CT3c and one of the capacitors C3a, C3b and C3c, may be connected to one of the wordlines WL13, WL23 and WL33 and the local bitline LBL21, and may correspond to the memory cells MC31 in FIG. 1. Although not shown, bit line selection transistors may be disposed between each of the cell transistors CT1a, CT1b, CT1c, CT2a, CT2b, CT2c, CT3a, CT3b, CT3c, CT4a, CT4b and CT4c and the local bitlines LBL11 Each of the memory cells MC4a, MC4b and MC4c may include one of the cell transistors CT4a, CT4b and CT4c and one of the capacitors C4a, C4b and C4c, may be connected to one of the wordlines WL14, WL24 and WL34 and the local bitline LBL21, and may correspond to the memory cells MC41 in FIG. 1.

Each of the local bitline multiplexers MUX11 and MUX21 may include two transistors. Among the two transistors, one transistor may be connected between one of the local bitlines LBL11 and LBL21 and the global bitline GBL1, and the other transistor may be connected between one of the local bitlines LBL11 and LBL21 and a precharge voltage VBL.

For example, the local bitline multiplexer MUX11 may include transistors T11a and T11b. The transistor T11a may be connected between the local bitline LBL11 and the global bitline GBL1, and may have a gate electrode connected to a control line CL1a. The transistor T11b may be connected between the local bitline LBL11 and the precharge voltage VBL, and may have a gate electrode connected to a control line CL1b.

Similarly, the local bitline multiplexer MUX21 may include a transistor T21a that is connected between the local bitline LBL21 and the global bitline GBL1 and has a gate electrode connected to a control line CL2a, and may include a transistor T21b that is connected between the local bitline LBL21 and the precharge voltage VBL and has a gate electrode connected to a control line CL2b.

Among the transistors T11a, T11b, T21a and T21b included in the local bitline multiplexers MUX11 and MUX21, the transistors T11a and T21a that control the electrical connection between the local bitline and the global bitline may be referred to as selection transistors, and the transistors T11b and T21b that are connected to the precharge voltage VBL may be referred to as keeper transistors. For example, the transistors T11a, T11b, T21a and T21b may be n-type metal oxide semiconductor (NMOS) transistors, but the present invention is not limited thereto.

In some example embodiments, the transistors T11a, T11b, T21a and T21b that are included in the local bitline multiplexers MUX11 and MUX21, the control lines CL1a, CL1b, CL2a and CL2b that are connected to the transistors T11a, T11b, T21a and T21b, the cell transistors CT1a, CT1b, CT1c, CT2a, CT2b, CT2c, CT3a, CT3b, CT3c, CT4a, CT4b and CT4c that are included in the memory cells MC1a, MC1b, MC1c, MC2a, MC2b, MC2c, MC3a, MC3b, MC3c, MC4a, MC4b and MC4c, and the wordlines WL11, WL21, WL31, WL12, WL22, WL32, WL13, WL23, WL33, WL14, WL24 and WL34 that are connected to the cell transistors CT1a, CT1b, CT1c, CT2a, CT2b, CT2c, CT3a, CT3b, CT3c, CT4a, CT4b and CT4c may be formed or fabricated through the same manufacturing process.

For example, the control lines CL1a, CL1b, CL2a and CL2b and the wordlines WL11, WL21, WL31, WL12, WL22, WL32, WL13, WL23, WL33, WL14, WL24 and WL34 may include a plurality of structures formed through the same manufacturing process. Among the plurality of structures, the uppermost structures may be used as the control lines CL1a, CL1b, CL2a and CL2b, and the remaining structures other than the uppermost structures may be used as the wordlines WL11, WL21, WL31, WL12, WL22, WL32, WL13, WL23, WL33, WL14, WL24 and WL34. For example, the control line CL1b may be disposed on the wordlines WL11, WL21 and WL31, the control line CL1a may be disposed on the wordlines WL12, WL22 and WL32, the control line CL2b may be disposed on the wordlines WL13, WL23 and WL33, and the control line CL2a may be disposed on the wordlines WL14, WL24 and WL34.

For example, a plurality of transistors may be formed to be connected to the plurality of structures. Among the plurality of transistors, the uppermost transistors that are connected to the uppermost structures may be used as the transistors T11a, T11b, T21a and T21b, and the remaining transistors other than the uppermost transistors that are connected to the remaining structures other than the uppermost structures may be used as the cell transistors CT1a, CT1b, CT1c, CT2a, CT2b, CT2c, CT3a, CT3b, CT3c, CT4a, CT4b and CT4c. For example, capacitors that are connected to the remaining transistors may be formed and may be used as the capacitors C1a, C1b, C1c, C2a, C2b, C2c, C3a, C3b, C3c, C4a, C4b and C4c, and the formation of capacitors connected to the uppermost transistors may be omitted.

As described above, the structures at the uppermost level of the memory cell array included in the 3D semiconductor memory device may be used as the local bitline multiplexers rather than the memory cells, and thus the semiconductor memory device may have improved electrical characteristics and improved reliability.

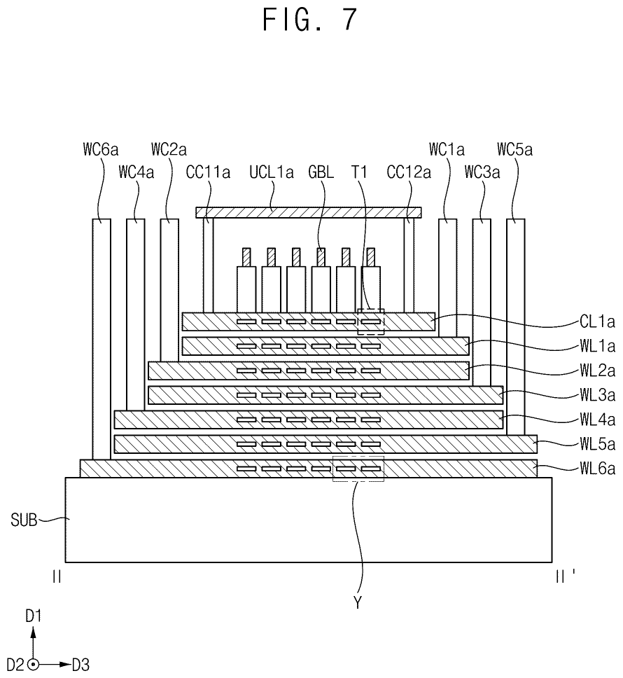

First and second control contacts CC11a and CC12a may be connected to a first end and a second end of the control line CL1a, respectively, and first and second control contacts CC21a and CC22a may be connected to a first end and a second end of the control line CL2a, respectively. A signal for turning on and off the local bitline multiplexer MUX11 by switching the transistor T11a may be applied simultaneously to both ends of the control line CL1a through the first and second control contacts CC11a and CC12a. For example, the signal may be applied simultaneously to the first and second control contacts CC11a and CC12a through a line (e.g., UCL1a of FIG. 7) connected to the first and second control contacts CC11 a and CC12 a. A signal for turning on and off the local bitline multiplexer MUX21 by switching the transistor T21a may be applied simultaneously to both ends of the control line CL2a through the first and second control contacts CC21a and CC22a. For example, the signal may be applied simultaneously to the first and second control contacts CC21a and CC22a through a line (not shown) connected to the first and second control contacts CC21a and CC22a.

As described above, the control line may be driven using the control contacts at both ends of the control line, and thus the semiconductor memory device may have improved electrical characteristics and improved reliability. The operation of driving the control line using the control contacts at both ends of the control line may be referred to as a two side driving (TSD) scheme.

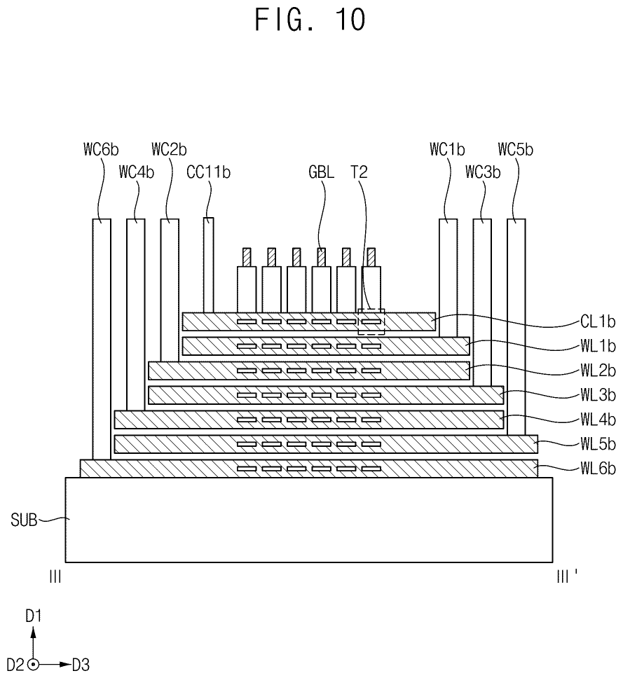

In some example embodiments, as will be described with reference to FIG. 7, the semiconductor memory device may further include a plurality of wordline contacts each of which is connected to one of the wordlines WL11, WL21, WL31, WL12, WL22, WL32, WL13, WL23, WL33, WL14, WL24 and WL34. In some example embodiments, as will be described with reference to FIG. 10, the semiconductor memory device may further include at least one control contact that is connected to one of the control lines CL1b and CL2b.

Although not illustrated in detail, components that are connected to the local bitlines LBL12 and LBL22 and the global bitline GBL12, e.g., the memory cells MC12, MC22, MC32 and MC42 and the local bitline multiplexers MUX12 and MUX22 may also be implemented similarly to those described with reference to FIG. 2. Therefore, the selection transistors and the keeper transistors that are included in the local bitline multiplexers MUX11 and MUX12 may share the control line CL1a and the control line CL1b, respectively, and the selection transistors and the keeper transistors that are included in the local bitline multiplexers MUX21 and MUX22 may share the control line CL2a and the control line CL2b, respectively.

In some example embodiments, although not illustrated in FIG. 2, the semiconductor memory device may be implemented with a wordline merging structure in which wordlines (e.g., the wordlines WL12 and WL13) connected to memory cells (e.g., the memory cells MC2a and MC3a) that do not share a local bitlines may be merged into one wordline. In some example embodiments, although not illustrated in FIG. 2, the semiconductor memory device may be implemented such that the local bitline multiplexers MUX11 and MUX21 are connected to different global bitlines rather than the same global bitline (e.g., the global bitline GBL1).

In the semiconductor memory device according to example embodiments, adjacent memory cells may share the local bitline. In addition, the local bitline multiplexer that controls the electrical connection between the local bitline and the global bitline may be disposed on each local bitline, and the structures at the uppermost level of the memory cell array may be used as the local bitline multiplexer. Further, two control contacts for signal application may be disposed at both ends of the control line that is connected to the local bitline multiplexer. Accordingly, the semiconductor memory device may have improved electrical characteristics and improved reliability.

For example, the local bitline and the global bitline may be selectively electrically connected and disconnected using the local bitline multiplexer, and thus the capacitance (e.g., bit line capacitance (CBL)) of the bitline may be reduced and the sensing margin may increase. In addition, the signal for turning on and off of the local bitline multiplexer may be applied to the control line using two control contacts, the delay time when the local bitline multiplexer is turned on/off may be reduced and the operating performance may be improved.

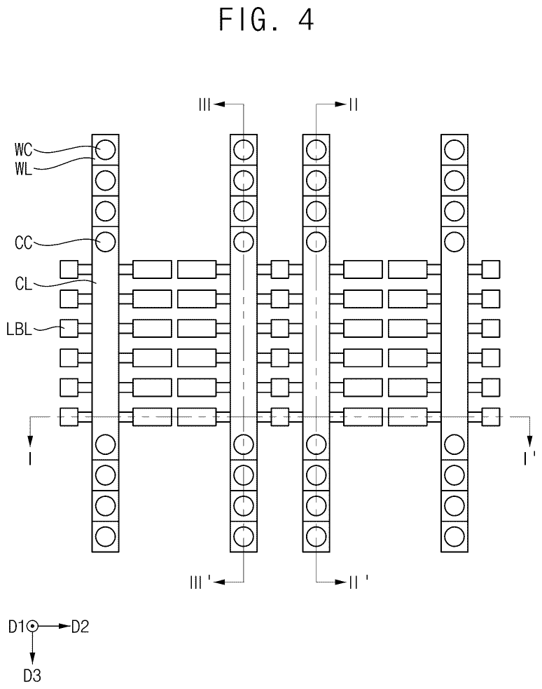

FIGS. 3 and 4 are a perspective view and a plan view for describing a semiconductor memory device according to example embodiments.

Referring to FIGS. 3 and 4, a portion of the memory cell array of the semiconductor memory device and/or a portion of a sub-cell array included in the memory cell array is illustrated.

The semiconductor memory device may include wordlines WL, wordline contacts (or contact plugs) WC, control lines CL, control contacts CC, local bitlines LBL, global bitlines GBL, memory cells and local bitline multiplexers that are formed or disposed on a substrate SUB. Although not illustrated in detail, the semiconductor memory device may further include an insulating interlayer that is disposed on the substrate SUB and covers the above structures. For convenience of illustration, the global bitlines GBL are omitted in FIG. 4.

The substrate SUB may include a semiconductor material, e.g., silicon, germanium, silicon-germanium, etc., or a III-V group compound semiconductor, such as GaP, GaAs, GaSb, etc. In some example embodiments, the substrate SUB may be a silicon-on-insulator (SOI) substrate or a germanium-on-insulator (GOI) substrate.

The substrate SUB may include a first region and a second region. The first region may be a region in which the memory cells are formed, and the second region may be a region in which the wordline contacts WC and the control contacts CC for transmitting electrical signals to the memory cells are formed. The first region and the second region may be referred to as a cell region and an extension region, respectively.

The substrate SUB may further include a third region in which peripheral circuit patterns including sense amplifiers, etc. are formed. The third region may be referred to as a peripheral circuit region. In some example embodiments, the third region may at least partially surround the first and second regions, or may be disposed under or over the substrate SUB, so that the semiconductor memory device may have a cell over periphery (COP) structure or a periphery over cell (POC) structure. As used herein, the phrase “at least partially surround” is understood to mean that the surrounding element contacts the surrounded element on at least one side or portion thereof, may contact the surrounded element on two sides, whether those sides are opposite sides or proximate sides, may contact the surrounded element on more than two sides, and may even completely surround the surrounded element.

Each of the local bitlines LBL may extend in the first direction D1 on the first region of the substrate SUB, and a plurality of local bitlines LBL may be spaced apart from each other in the second and third directions D2 and D3. The memory cells and transistors included in the local bitline multiplexers may be formed between two adjacent local bitlines LBL.

Each of the global bitlines GBL may extend in the second direction D2 on the first region of the substrate SUB and on the local bitlines LBL, and a plurality of global bitlines GBL may be spaced apart from each other in the third direction D3.

Each of the wordlines WL and each of the control lines CL may extend in the third direction D3 on the first and second regions of the substrate SUB, a plurality of wordlines WL and a plurality of control lines CL may be spaced apart from each other in the second direction D2, and some wordlines WL and one control line CL may be stacked in the first direction D1. Each of the wordline contacts WC and each of the control contacts CC may extend in the first direction D1 on the second region of the substrate SUB, and may be electrically connected to one of the wordlines WL and one of the control lines CL, respectively.

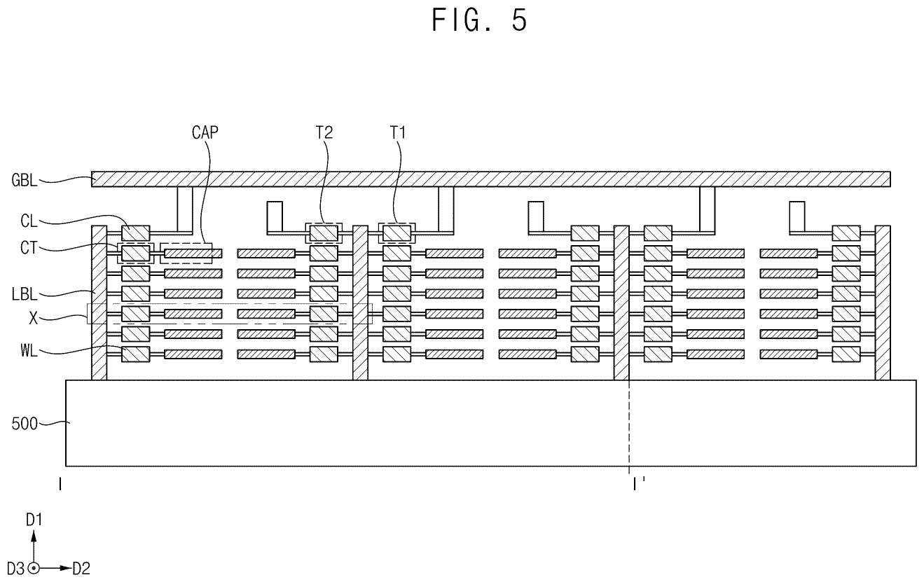

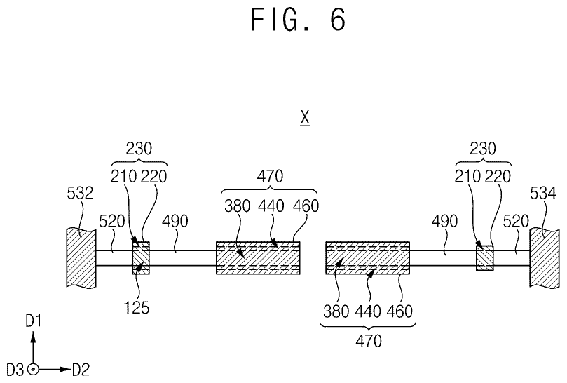

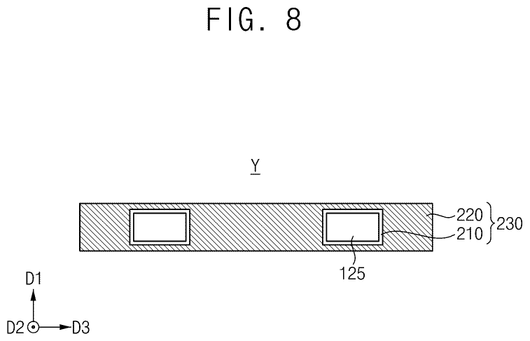

FIGS. 5, 6, 7 and 8 are cross-sectional views for describing a semiconductor memory device of FIGS. 3 and 4 according to example embodiments. For example, FIG. 5 is a cross-sectional view taken along a line I-I′ in FIG. 4, FIG. 6 is a detailed cross-sectional view of a region X in FIG. 5, FIG. 7 is a cross-sectional view taken along a line II-II′ in FIG. 4, and FIG. 8 is a detailed cross-sectional view of a region Y in FIG. 7.

Referring to FIGS. 5, 6, 7 and 8, the memory cells may include cell transistors CT and capacitors CAP, and the local bitline multiplexers may include select transistors T1 and keeper transistors T2.

For example, structures 532 and 534 in FIG. 6 may represent or correspond to two local bitlines that extend in the first direction D1 and are spaced apart in the second direction D2. For example, an upper surface of each of the local bitlines 532 and 534 may have a shape of, e.g., a polygon, a polygon with rounded corners, a circle, an ellipse, etc.

Between two adjacent local bitlines 532 and 534, two memory cells may be formed at the remaining levels other than the uppermost level. For example, each memory cell may include the capacitor CAP and the cell transistor CT. For example, in FIG. 6, one cell transistor may be formed between a capacitor 470 on the left side and the local bitline 532, and another cell transistor may be formed between a capacitor 470 on the right side and the local bitline 534. For example, each cell transistor may include a second source/drain 490, a channel 125 and a first source/drain 520 sequentially disposed between the capacitor 470 and each of the local bitlines 532 and 534, and a gate structure 230 surrounding the channel 125.

In some example embodiments, the capacitor 470 may include a first capacitor electrode 380 having a pillar shape extending in the second direction D2, a dielectric pattern 440 having a shape of a hollow cylinder that may surround a surface, for example, lower and upper surfaces and opposite sidewalls in the third direction D3 of the first capacitor electrode 380, and a second capacitor electrode 460 having a hollow cylinder that may surround a surface, for example, lower and upper surfaces and opposite outer sidewalls in the third direction D3 of the dielectric pattern 440. However, example embodiments are not necessarily limited thereto, and for example, the first capacitor electrode 380 may have a shape of a hollow cylinder instead of the pillar shape, and the second capacitor electrode 460 may have a shape of a hollow cylinder instead of the pillar shape.

In some example embodiments, a cross-section in the third direction D3 of the first capacitor electrode 380 may have a shape of a rectangle. However, example embodiments are not necessarily limited thereto, and the cross-section in the third direction D3 of the first capacitor electrode 380 may have a shape of, e.g., a polygon, a polygon with rounded corners, a circle, an ellipse, etc.

Each of the first and second capacitor electrodes 380 and 460 may include an electrically conductive material, e.g., a metal, a metal nitride, a metal silicide, doped silicon-germanium, etc. The dielectric pattern 440 may include a metal oxide having a high dielectric constant, e.g., hafnium oxide, zirconium oxide, etc., or a ferroelectric material. As used herein, the phrase, “high dielectric constant” may be understood to be a dielectric constant greater than that of silicon oxide.

The channel 125 may include a semiconductor material, e.g., silicon, germanium, silicon-germanium, etc. Alternatively, the channel 125 may include an oxide semiconductor material such as zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓOyN_{z}), magnesium zinc oxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn_{z}Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}ZnₐO_{d}), silicon indium zinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zinc tin oxide (GaₓZn_{y}Sn_{z}Oₐ), zirconium zinc tin oxide (ZrₓZn_{y}Sn_{z}Oₐ), and/or indium gallium silicon oxide (InGaSiO).

Each of the first and second source/drain 520 and 490 may include substantially the same material as the channel 125, however, n-type or p-type impurities may be doped thereinto. The first and second source/drain 520 and 490 may include the same conductivity type of impurities.

In some example embodiments, the gate structure 230 may include a gate insulation pattern 210 covering a surface, for example, lower and upper surfaces and opposite sidewalls in the third direction D3 of the channel 125, and a gate electrode 220 covering a surface, for example, lower and upper surfaces and opposite outer sidewalls in the third direction D3 of the gate insulation pattern 210. Thus, the channel 125 may extend through the gate structure 230 in the second direction D2, and the gate structure 230 may have a gate all around (GAA) structure surrounding the channel 125.

Alternatively, the gate structure 230 may have a single gate structure or a double gate structure instead of the GAA structure. For example, the gate structure 230 may be disposed on or beneath the channel 125, or two gate structures 230 may be disposed on and beneath, respectively, the channel 125, instead of surrounding the channel 125.

As a result, if only the gate structure 230 is electrically connected to the channel 125, the gate structure 230 may have various other types of structures.

In addition, between two adjacent local bitlines 532 and 534, the selection transistor T1 and the keeper transistor T2 may be formed at the uppermost level. For example, each of the selection transistor T1 and the keeper transistor T2 may have a structure the same as that of the cell transistor CT included in each memory cell. For example, the selection transistor T1 may be connected to the global bitline GBL through a vertical via, and the keeper transistor T2 may be connected to the bitline voltage VBL through a vertical via. For example, structures corresponding to the capacitors 470 may not be formed and may be omitted at the uppermost level.

In some example embodiments, the gate electrodes 220, which surround the channels 125 arranged along the third direction D3 at the same level and the gate insulation patterns 210 covering the channels 125 and are disposed adjacent to each other in the third direction D3, may be connected to each other, and thus may form one wordline WL and/or one control line CL extending in the third direction D3 on the first and second regions of the substrate SUB. For example, the gate electrode 220 at the uppermost level may form the control line CL, and the gate electrodes 220 at the remaining levels other than the uppermost level may form the wordlines WL.

The gate electrode 220 may include an electrically conductive material, e.g., a metal, a metal nitride, a metal silicide, etc., and the gate insulation pattern 210 may include an oxide, e.g., silicon oxide, a metal oxide, etc.

In some example embodiments, each of the wordline contacts WC and each of the control contacts CC may extend in the first direction D1 on the second region of the substrate SUB, and may be electrically connected to one of the wordlines WL and one of the control lines CL, respectively. For example, the control line CL and the wordlines WL may be disposed scalariformly, that is, in a step shape (e.g., in the third direction D3 in a stepwise manner) on the second region of the substrate SUB. For example, lengths in the third direction D3 of the control line CL and the wordlines may increase from the uppermost level to the lowermost level.

For example, the control line CL1a connected to the selection transistor T1 and wordlines WL1a, WL2a, WL3a, WL4a, WL5a and WL6a disposed under the control line CL1a and connected to the memory cells may be arranged and formed in a step shape as illustrated in FIG. 7.

For example, the first control contact CC11a may be connected to the first end of the control line CL1a, and the second control contact CC12a may be connected to the second end of the control line CL1a. The first and second control contacts CC11a and CC12a may be connected through an upper wiring UCL1a, and a signal for turning on and off the local bitline multiplexer (e.g., the selection transistor T1) may be applied simultaneously to both ends of the control line CL1a through the upper wiring UCL1a and the control contacts CC11a and CC12a.

For example, wordline contacts WC1a, WC2a, WC3a, WC4a, WC5a and WC6a may be connected to the wordlines WL1a, WL2a, WL3a, WL4a, WL5a and WL6a, respectively. For example, when the lowermost wordline (e.g., the wordline WL6a at the lowermost level) is defined as a first wordline, the wordlines WL2a, WL4a and WL6a may be defined as wordlines at odd-numbered levels, and the wordlines WL1a, WL3a and WL5a may be defined as wordlines at even-numbered levels. In this example, among the wordline contacts WC1a, WC2a, WC3a, WC4a, WC5a and WC6a, the wordline contacts WC2a, WC4a and WC6a may be connected to first ends of the wordlines WL2a, WL4a and WL6a at odd-numbered levels, and the wordline contacts WC1a, WC3a and WC5a may be connected to second ends of the wordlines WL1a, WL3a and WL5a at even-numbered levels.

Although not illustrated in detail, wirings similar to the upper wiring UCL1a may be formed at the top of the wordline contacts WC1a, WC2a, WC3a, WC4a, WC5a and WC6a.

As described above, a region where the wordline contacts connected to the wordlines at odd-numbered levels are disposed and a region where the wordline contacts connected to wordlines at even-numbered levels are disposed may be different from each other. However, example embodiments are not limited thereto. For example, the wordlines may be arbitrarily divided into two groups, and a region where wordline contacts connected to wordlines of one group are disposed and a region where wordline contacts connected to wordlines of the other group are disposed may be different from each other.

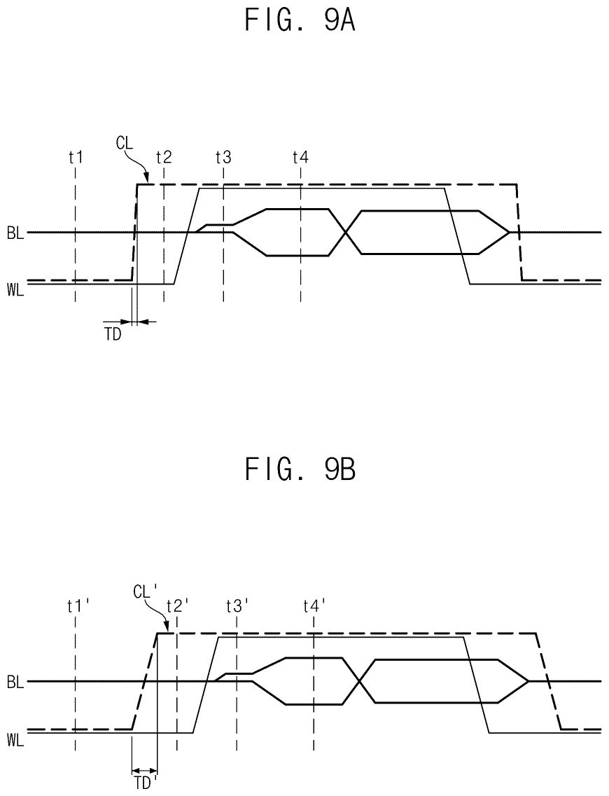

FIGS. 9A and 9B are diagrams for describing an operation of a semiconductor memory device according to example embodiments.

Referring to FIG. 9A, an example of an operation of the semiconductor memory device according to example embodiments in which the control line is driven using two control contacts connected to both ends of the control line is illustrated. For example, FIG. 9A illustrates voltage changes on the wordline WL, a bitline BL and the control line CL connected to a specific memory cell when the specific memory cell is to be accessed. When the specific memory cell is selected the bitline BL may be electrically connected to the local bitline LBL and the global bitline GBL.

At a time point t1, the bitline BL may have a precharge state.

Thereafter, when the control line CL transitions from a low level to a high level, the selection transistor T1 included in the local bitline multiplexer may be turned on. Thus, at a time point t2, the local bitline LBL and the global bitline GBL may be electrically connected to each other. Since the signal is applied using two control contacts at both ends of the control line CL, the RC delay time may decrease, and a delay time TD for the control line CL to transition from the low level to the high level may be relatively short.

Thereafter, when the wordline WL transitions from the low level to the high level, the corresponding memory cell may be accessed. At a time point t3, the bitline BL may have a charge sharing state, and at a time point t4, the bitline BL may have a develop state. Therefore, an operation (e.g., a read operation) for the corresponding memory cell may be performed.

Referring to FIG. 9B, an example of an operation of a conventional semiconductor memory device in which a control line is driven using a single control contact connected to one end of the control line is illustrated. The descriptions repeated with or overlapping with descriptions of FIG. 9A will be omitted in the interest of brevity.

At a time point t1′, the bitline BL may have the precharge state. Thereafter, at a time point t2′, the local bitline LBL and the global bitline GBL may be electrically connected to each other. Thereafter, at a time point t3′, the bitline BL may have the charge sharing state, and at a time point t4′, the bitline BL may have the develop state. Since the signal is applied using one control contact when the local bitline LBL and the global bitline GBL are electrically connected, the RC delay time may increase, and a delay time TD′ for a control line CL′ to transition from the low level to the high level may be relatively large.

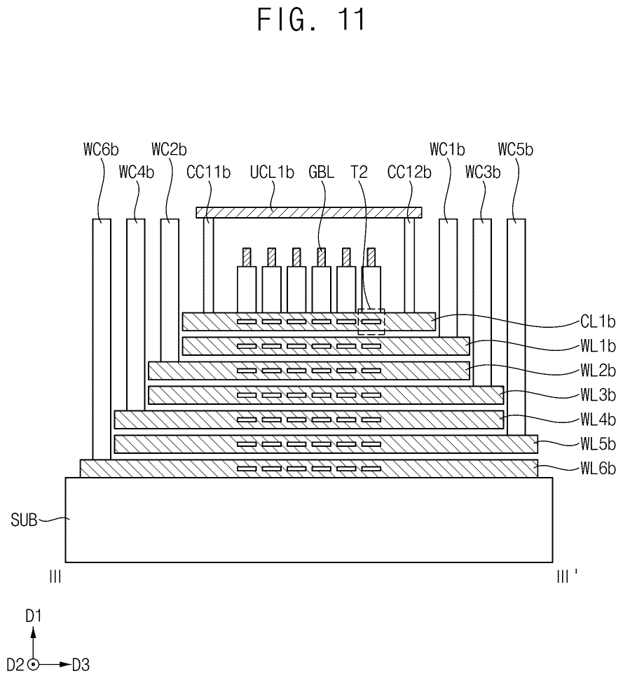

FIGS. 10 and 11 are cross-sectional views for describing the semiconductor memory device of FIGS. 3 and 4 according to example embodiments. For example, FIGS. 10 and 11 are cross-sectional views taken along a line III-III′ in FIG. 4. The descriptions repeated with or overlapping with descriptions of FIG. 7 will be omitted in the interest of brevity.

Referring to FIG. 10, the control line CL1b connected to the keeper transistor T2 and wordlines WL1b, WL2b, WL3b, WL4b, WL5b and WL6b under the control line CL1b and connected to memory cells may be disposed and formed in a step shape.

For example, a first control contact CC11b may be connected to a first end of the control line CL1b. For example, unlike the control line CL1a connected to the gate electrode of the selection transistor T1, the control line CL1b connected to the gate electrode of the keeper transistor T2 may not be implemented with the two side driving scheme and may be connected to only one control contact CC11b.

For example, wordline contacts WC1b, WC2b, WC3b, WC4b, WC5b and WC6b may be connected to the wordlines WL1b, WL2b, WL3b, WL4b, WL5b and WL6b, respectively. For example, among the wordline contacts WC1b, WC2b, WC3b, WC4b, WC5b and WC6b, the wordline contacts WC2b, WC4b and WC6b may be connected to first ends of the wordlines WL2b, WL4b and WL6b at odd-numbered levels, respectively, and the wordline contacts WC1b, WC3b and WC5b may be connected to second ends of the wordlines WL1b, WL3b and WL5b at even-numbered levels, respectively.

Referring to FIG. 11, the arrangement of the control line CL1b and the wordlines WL1b, WL2b, WL3b, WL4b, WL5b and WL6b and the arrangement of the wordline contacts WC1b, WC2b, WC3b, WC4b, WC5b and WC6b may be the same as those described with reference to FIG. 10.

For example, the first control contact CC11b may be connected to the first end of the control line CL1b, and a second control contact CC12b may be connected to a second end of the control line CL1b. For example, similarly to the control line CL1a connected to the gate electrode of the selection transistor T1, the control line CL1b connected to the gate electrode of the keeper transistor T2 may also be implemented with the two side driving scheme. In this example, the first and second control contacts CC11b and CC12b may be connected through an upper wiring UCL1b, and a signal for applying the precharge voltage VBL (e.g., a signal for turning on and off the keeper transistor T2) may be applied simultaneously to both ends of the control line CL1b through the upper wiring UCL1b and the control contacts CC11b and CC12b.

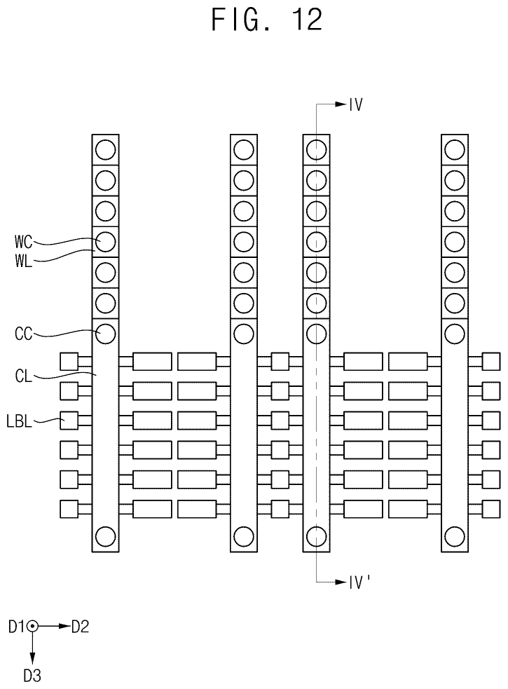

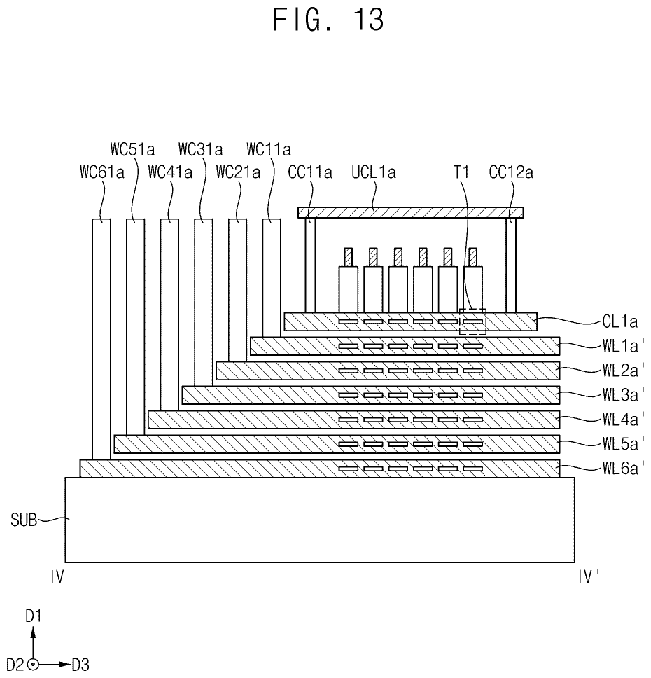

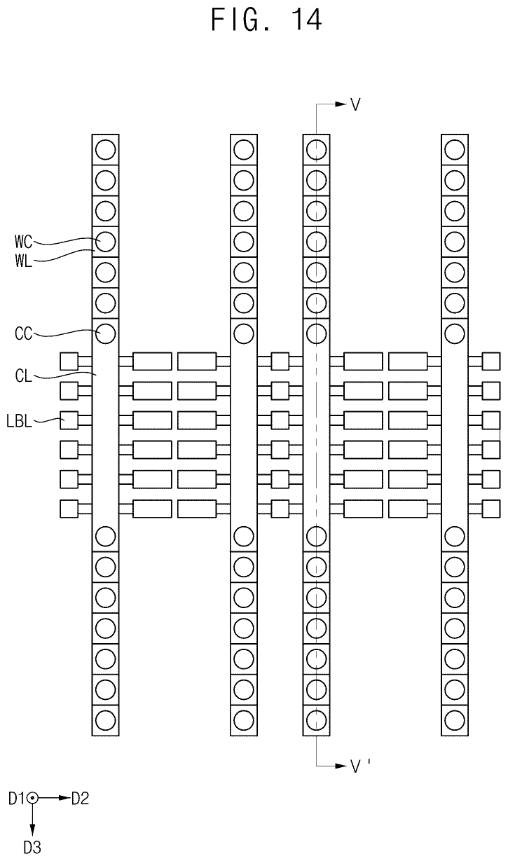

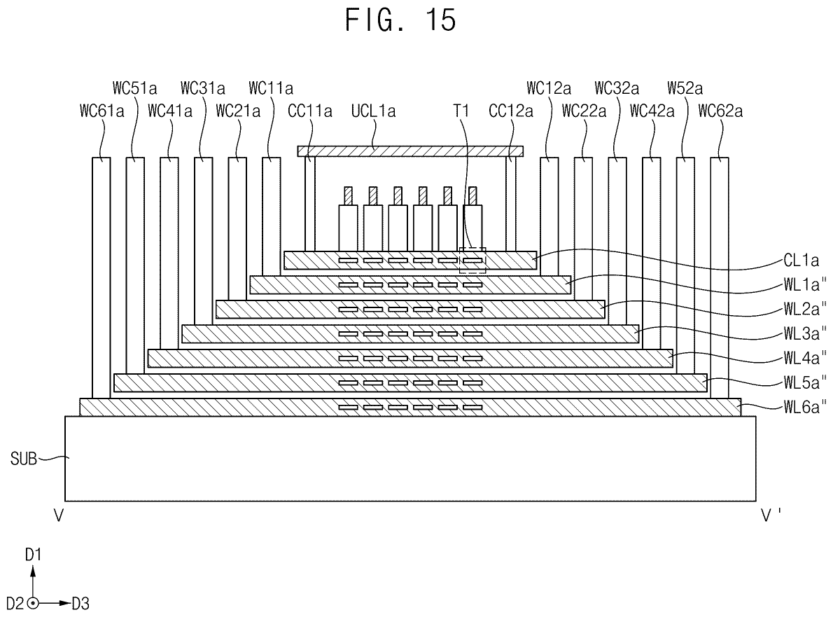

FIGS. 12, 13, 14 and 15 are perspective views and plan views for describing a semiconductor memory device according to example embodiments. For example, FIGS. 12 and 14 are perspective views of a semiconductor memory device, and FIG. 13 is a cross-sectional view taken along a line IV-IV′ in FIG. 12, and FIG. 15 is a cross-sectional view taken along a line V-V′ in FIG. 14. The descriptions repeated with or overlapping with descriptions of FIGS. 4 and 7 will be omitted in the interest of brevity.

Referring to FIGS. 12 and 13, the control line CL1a connected to the selection transistor T1 and wordlines WL1a′, WL2a′, WL3a′, WL4a′, WL5a′ and WL6a′ under the control line CL1a and connected to memory cells may be disposed and formed in a step shape. The control line CL1a, the control contacts CC11a and CC12a and the upper wiring UCL1a may be the same as those described with reference to FIG. 7.

For example, wordline contacts WC11a, WC21a, WC31a, WC41a, WC51a and WC61a may be connected to the word lines WL1a′, WL2a′, WL3a′, WL4a′, WL5a′ and WL6a′, respectively. For example, the wordline contacts WC11a, WC21a, WC31a, WC41a, WC51a and WC61a may be connected to first ends of the wordlines WL1a′, WL2a′, WL3a′, WL4a′, WL5a′ and WL6a′, respectively. For example, unlike the example of FIG. 7, the wordline contacts connected to all wordlines may be disposed in the same region (e.g., a left region).

Referring to FIGS. 14 and 15, the control line CL1a connected to the selection transistor T1 and wordlines WL1a″, WL2a″, WL3a″, WL4a″, WL5a″ and WL6a″ under the control line CL1a and connected to memory cells may be disposed and formed in a step shape. The control line CL1a, the control contacts CC11a and CC12a and the upper wiring UCL1a may be substantially the same as those described with reference to FIG. 7.

For example, wordline contacts WC11a, WC12a, WC21a, WC22a, WC31a, WC32a, WC41a, WC42a, WC51a, WC52a, WC61a and WC62a may be connected to the wordlines WL1a″, WL2a″, WL3a″, WL4a″, WL5a″ and WL6a″. For example, the wordline contacts WC11a, WC21a, WC31a, WC41a, WC51a and WC61a may be connected to first ends of the wordlines WL1a″, WL2a″, WL3a″, WL4a″, WL5a″ and WL6a″, respectively, and the wordline contacts WC12a, WC22a, WC32a, WC42a, WC52a and WC62a may be connected to second ends of the wordlines WL1a″, WL2a″, WL3a″, WL4a″, WL5a″ and WL6a″, respectively. In other words, similarly to the control line CL1a, each wordline may be driven using two wordline contacts connected to both ends of each wordline.

Although FIGS. 3 through 15 illustrate examples of the semiconductor memory devices that include specific numbers and configurations of control lines, control line contacts, wordlines and wordline contacts, the present invention is not limited thereto.

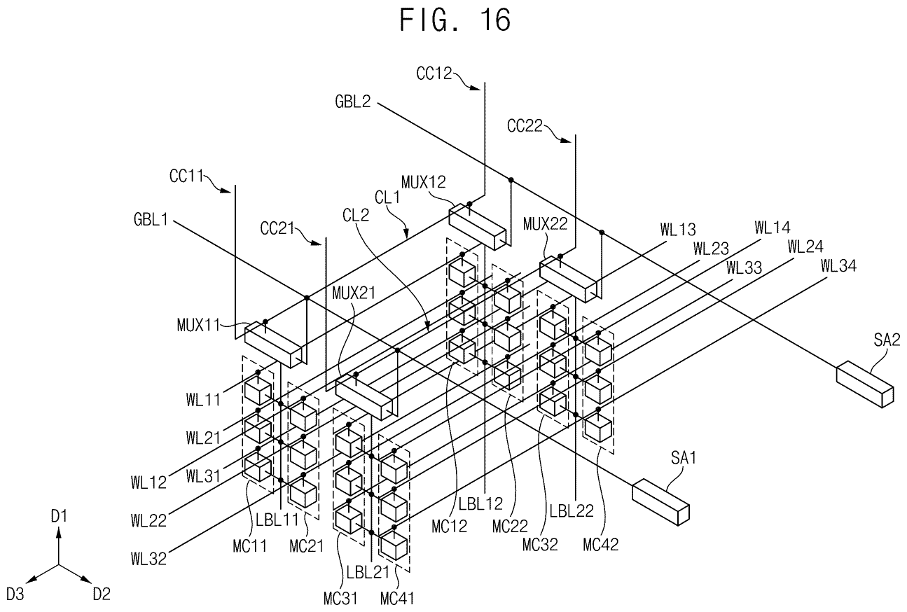

FIG. 16 is a perspective view of a semiconductor memory device according to example embodiments. The descriptions repeated with or overlapping with descriptions of FIG. 1 will be omitted in the interest of brevity.

Referring to FIG. 16, a portion of a memory cell array of a semiconductor memory device is illustrated, and a portion of a peripheral circuit connected to the portion of the memory cell array is illustrated. As compared with the semiconductor memory device of FIG. 1, the semiconductor memory device of FIG. 16 may further include a plurality of sense amplifiers SA1 and SA2.

For example, the plurality of memory cells MC11, MC21, MC31, MC41, MC12, MC22, MC32 and MC42, the plurality of local bitlines LBL11, LBL21, LBL12 and LBL22, the plurality of global bitlines GBL1 and GBL2, the plurality of wordlines WL11, WL21, WL31, WL12, WL22, WL32, WL13, WL23, WL33, WL14, WL24 and WL34, the plurality of control lines CL1 and CL2, the plurality of local bitline multiplexers MUX11, MUX21, MUX12 and MUX22, the plurality of first control contacts CC11 and CC21, and the plurality of second control contacts CC12 and CC22 may be included in the memory cell array (or the portion thereof). For example, the plurality of sense amplifiers SA1 and SA2 may be included in the peripheral circuit (or the portion thereof).

The plurality of sense amplifiers SA1 and SA2 may be electrically connected to the plurality of global bitlines GBL1 and GBL2, and may drive the plurality of local bitlines LBL11, LBL21, LBL12 and LBL22 and the plurality of global bitlines GBL1 and GBL2.

For example, the sense amplifier SA1 may be electrically connected to the global bitline GBL1, may drive the local bitline LBL11 and the global bitline GBL1 when the local bitline LBL11 and the global bitline GBL1 are electrically connected through the local bitline multiplexer MUX1, and may drive the local bitline LBL21 and the global bitline GBL1 when the local bitline LBL21 and the global bitline GBL1 are electrically connected through the local bitline multiplexer MUX21.

Similarly, the sense amplifier SA2 may be electrically connected to the global bitline GBL2, may drive the local bitline LBL12 and the global bitline GBL2 when the local bitline LBL12 and the global bitline GBL2 are electrically connected through the local bitline multiplexer MUX12, and may drive the local bitline LBL22 and the global bitline GBL2 when the local bitline LBL22 and the global bitline GBL2 are electrically connected through the local bitline multiplexer MUX22.

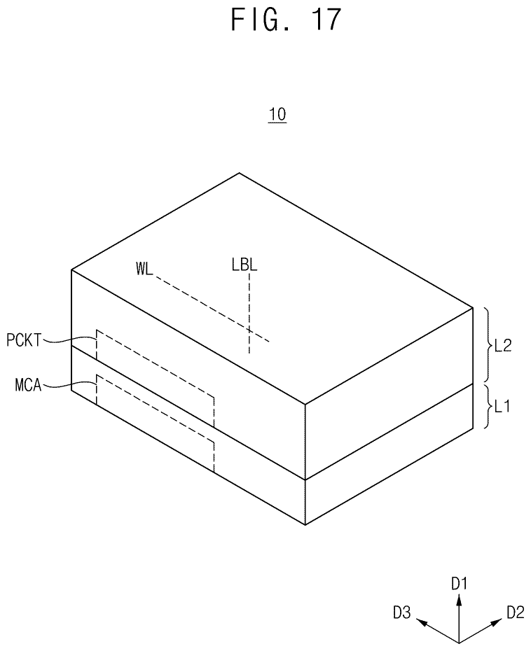

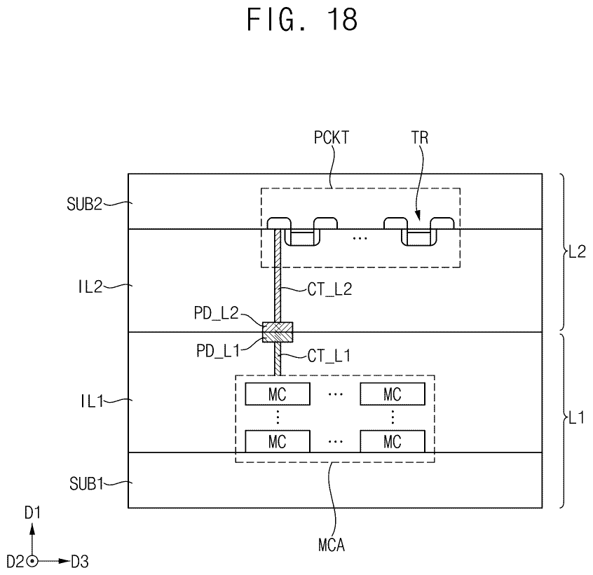

FIGS. 17 and 18 are a perspective view and a cross-sectional view of a semiconductor memory device according to example embodiments.

Referring to FIGS. 17 and 18, a semiconductor memory device 10 includes a first semiconductor layer L1 and a second semiconductor layer L2.

The first semiconductor layer L1 and the second semiconductor layer L2 are disposed or stacked in the first direction D1. For example, the second semiconductor layer L2 may be stacked on the first semiconductor layer L1 in the first direction D1, and the first semiconductor layer L1 may be disposed under (e.g., directly beneath or indirectly beneath) the second semiconductor layer L2 in the first direction D1. However, example embodiments are not limited thereto. For example, the semiconductor memory device 10 may be turned over during the manufacturing process, and thus the first semiconductor layer L1 may be stacked on the second semiconductor layer L2 in the first direction D1.

The first semiconductor layer L1 may include a first substrate SUB1, a memory cell array MCA, a plurality of wordlines WL and a plurality of local bitlines LBL. The first semiconductor layer L1 may further include a first bonding pad PD_L1, a first contact CT_L1 and a first insulating layer IL1. Thus, the first semiconductor layer L1 may be referred to as a memory cell region (MCR), a cell wafer, or a cell chip.

The first substrate SUB1 may be a supporting layer that supports components (or elements) of the first semiconductor layer L1. For example, the first substrate SUB1 may be a silicon substrate, and may be referred to as a base substrate. The first insulating layer IL1 may cover the components of the first semiconductor layer L1. For example, the first insulating layer IL1 may include a plurality of insulating layers.

The memory cell array MCA, the plurality of wordlines WL and the plurality of local bitlines LBL may be disposed and/or formed on the first substrate SUB1. For example, each of the plurality of wordlines WL may extend in the third direction D3, and the plurality of wordlines WL may be arranged along the first and second directions D1 and D2. For example, the plurality of wordlines WL may be spaced apart from each other in the first and second directions D1 and D2. For example, each of the plurality of local bitlines LBL may extend in the first direction D1, and the plurality of local bitlines LBL may be arranged along the second and third directions D2 and D3. For example, the memory cell array MCA may include a plurality of memory cells MC that are arranged along the first, second and third directions D1, D2 and D3, and each of the plurality of memory cells MC may be electrically connected to one of the plurality of wordlines WL and one of the plurality of local bitlines LBL.

The second semiconductor layer L2 may include a second substrate SUB2 and a peripheral circuit PCKT. The second semiconductor layer L2 may further include a second bonding pad PD_L2, a second contact CT_L2 and a second insulating layer IL2. Thus, the second semiconductor layer L2 may be referred to as a peripheral circuit region (PCR), a peripheral wafer, a core wafer, or a peripheral chip.

Similarly to the first substrate SUB1 and the first insulating layer IL1, the second substrate SUB2 may be a supporting layer that supports components of the second semiconductor layer L2, and the second insulating layer IL2 may cover the components of the second semiconductor layer L2.

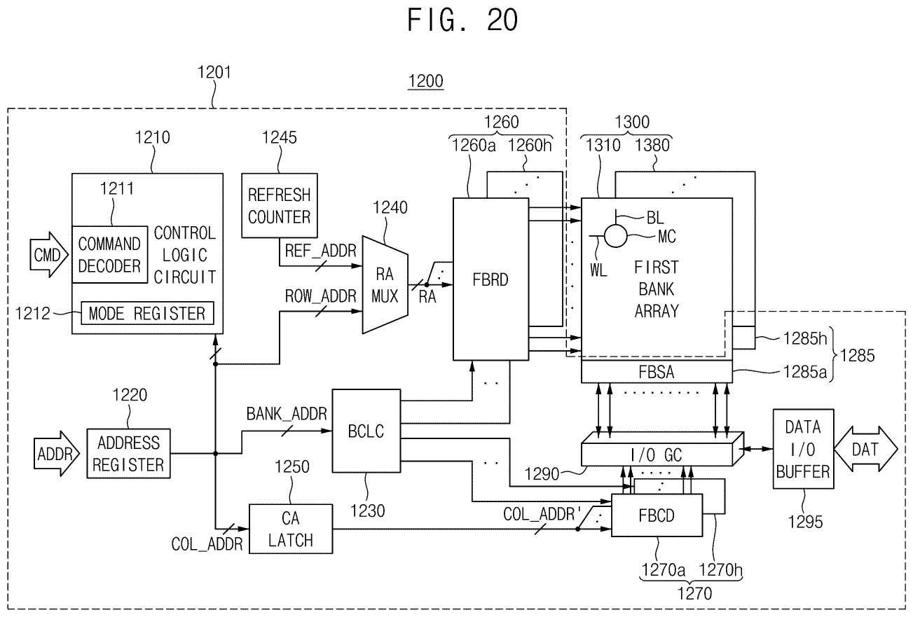

The peripheral circuit PCKT may be disposed and/or formed on the second substrate SUB2. For example, the peripheral circuit PCKT may include a plurality of transistors TR, and various circuits may be formed by the plurality of transistors TR. For example, as will be described with reference to FIG. 20, the peripheral circuit PCKT may include a sense amplifier unit, an input/output gating circuit, etc.

In some example embodiments, the first semiconductor layer L1 and the second semiconductor layer L2 may be manufactured separately, and then the first semiconductor layer L1 and the second semiconductor layer L2 may be connected to each other by a bonding scheme (or method). For example, the bonding scheme may represent a method of electrically or physically connecting a bonding metal pattern (e.g., the first bonding pad PD_L1) formed in the first semiconductor layer L1 with a bonding metal pattern (e.g., the second bonding pad PD_L2) formed in the second semiconductor layer L2. For example, the bonding pads PD_L1 and PD_L2 may be formed of copper (Cu), and the bonding scheme may be a Cu-Cu bonding scheme. Alternatively, the bonding pads PD_L1 and PD_L2 may be formed of aluminum (Al) or tungsten (W).

For example, the memory cell array MCA (e.g., the wordlines WL and the local bitlines LBL) of the first semiconductor layer L1 and the peripheral circuit PCKT of the second semiconductor layer L2 may be electrically connected to each other by the first and second bonding pads PD_L1 and PD_L2. For example, the memory cell MC and the transistor TR may be electrically connected to each other by the first and second contacts CT_L1 and CT_L2 and the first and second bonding pads PD_L1 and PD_L2. For example, the memory cell MC may be electrically connected to the first contact CT_L1 and the first bonding pad PD_L1, the transistor TR may be electrically connected to the second contact CT_L2 and the second bonding pad PD_L2, and the memory cell MC and the transistor TR may be electrically connected to each other by electrically connecting the first bonding pad PD_L1 with the second bonding pad PD_L2. Although not illustrated in detail, at least one conductive line and/or contact may be further formed to connect the memory cell MC with the first bonding pad PD_L1, and at least one conductive line and/or contact may be further formed to connect the transistor TR with the second bonding pad PD_L2.

However, example embodiments are not limited thereto, and various bonding schemes, such as a hybrid bonding scheme and a dielectric bonding scheme, may be used to electrically or physically connect the first semiconductor layer L1 with the second semiconductor layer L2.

The semiconductor memory device 10 according to example embodiments may have or adopt a structure in which the peripheral circuit PCKT and the memory cell array MCA are stacked, e.g., a periphery over cell (POC) structure in which the memory cell array MCA is formed below and then the peripheral circuit PCKT is stacked on the memory cell array MCA. Accordingly, the semiconductor memory device 10 may have a relatively small size. For example, the first semiconductor layer L1 may be manufactured by forming the memory cell array MCA on the first substrate SUB1, the second semiconductor layer L2 may be manufactured by forming the peripheral circuit PCKT on the second substrate SUB2, the first semiconductor layer L1 may be turned over, and the bonding pads PD_L1 and PD_L2 may be connected using the bonding scheme. As a result, the first and second semiconductor layers L1 and L2 may be electrically connected in the first direction D1.

However, example embodiments are not limited thereto, and the semiconductor memory device 10 may have or adopt a cell over periphery (COP) structure in which the peripheral circuit PCKT is formed below and then the memory cell array MCA is stacked on the peripheral circuit PCKT.

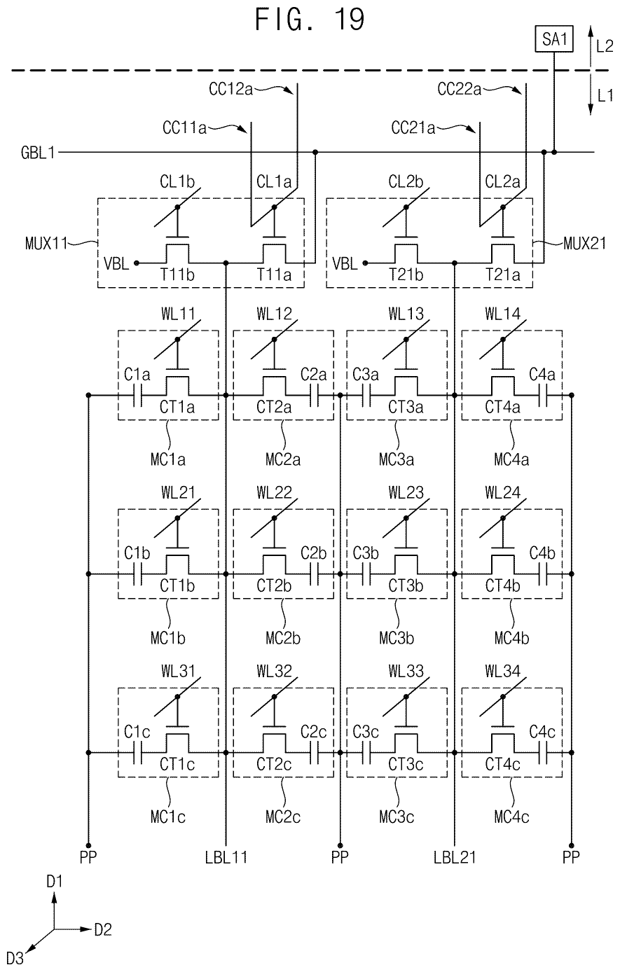

FIG. 19 is a circuit diagram illustrating the semiconductor memory device of FIGS. 16 and 17 according to example embodiments.

Referring to FIG. 19, an example of components that are connected to the local bitlines LBL11 and LBL21 and the global bitline GBL1 in the semiconductor memory device of FIGS. 16 and 17 is illustrated. The descriptions repeated with or overlapping with descriptions of FIGS. 2, 16, 17 and 18 will be omitted in the interest of brevity.

The local bitlines LBL11 and LBL21, the wordlines WL11, WL21, WL31, WL12, WL22, WL32, WL13, WL23, WL33, WL14, WL24 and WL34, the memory cells MC1a, MC1b, MC1c, MC2a, MC2b, MC2c, MC3a, MC3b, MC3c, MC4a, MC4b and MC4c, the local bitline multiplexers MUX11 and MUX21, the control lines CL1a, CL1b, CL2a and CL2b, the control contacts CC11a, CC12a, CC21a and CC22a, and the global bitline GBL1 may be disposed in the first semiconductor layer L1 (e.g., in the cell wafer), and may be disposed on the first substrate SUB1.

The sense amplifier SA1 may be disposed in the second semiconductor layer L2 (e.g., in the peripheral wafer), and may be disposed on the second substrate SUB2 different from the first substrate SUB1. In some example embodiments, when the second semiconductor layer L2 is turned over and when the first and second semiconductor layers L1 and L2 may be connected by the bonding scheme, the sense amplifier SA1 may be disposed under the second substrate SUB2.

However, example embodiments are not limited thereto, and at least one component may be additionally disposed in the second semiconductor layer L2.

In some example embodiments, the semiconductor memory device according to example embodiments may be implemented by combining two or more of the examples described with reference to FIGS. 1 through 19.

FIG. 20 is a block diagram illustrating a semiconductor memory device according to example embodiments.

Referring to FIG. 20, a semiconductor memory device 1200 may include a peripheral circuit 1201 and a memory cell array 1300. The peripheral circuit 1201 may include a control logic circuit 1210, an address register 1220, a bank control logic circuit 1230, a row address multiplexer 1240, a refresh counter 1245, a column address latch 1250, a row decoder 1260, a column decoder 1270, a sense amplifier unit 1285, an input/output (I/O) gating circuit 1290 and a data I/O buffer 1295. For example, the semiconductor memory device 1200 may be one of various volatile memory devices such as a dynamic random access memory (DRAM) device.

The memory cell array 1300 may include first to eighth bank arrays 1310 to 1380 (e.g., first to eighth bank arrays 1310, 1320, 1330, 1340, 1350, 1360, 1370 and 1380). The row decoder 1260 may include first to eighth bank row decoders 1260a to 1260h connected respectively to the first to eighth bank arrays 1310 to 1380. The column decoder 1270 may include first to eighth bank column decoders 1270a to 1270h connected respectively to the first to eighth bank arrays 1310 to 1380. The sense amplifier unit 1285 may include first to eighth bank sense amplifiers 1285a to 1285h connected respectively to the first to eighth bank arrays 1310 to 1380.

The first to eighth bank arrays 1310 to 1380, the first to eighth bank row decoders 1260a to 1260h, the first to eighth bank column decoders 1270a to 1270h, and the first to eighth bank sense amplifiers 1285a to 1285h may form first to eighth banks. Each of the first to eighth bank arrays 1310 to 1380 may include a plurality of wordlines WL, a plurality of bitlines BL, and a plurality of memory cells MC that are at intersections of the wordlines WL and the bitlines BL. For example, each of the plurality of bitlines BL may be connected to the local bitline LBL and the global bitline GBL that are selectively connected by the local bitline multiplexer. For example, when the local bitline multiplexer is selected, one of the plurality of bitlines BL may be electrically connected to the local bitline LBL and the global bitline GBL.

Although FIG. 20 illustrates the semiconductor memory device 1200 including eight banks (and eight bank arrays, eight row decoders, and so on), the semiconductor memory device 1200 may include any number of banks; for example, one, two, four, eight, sixteen, or thirty two banks, or any number therebetween one and thirty two.

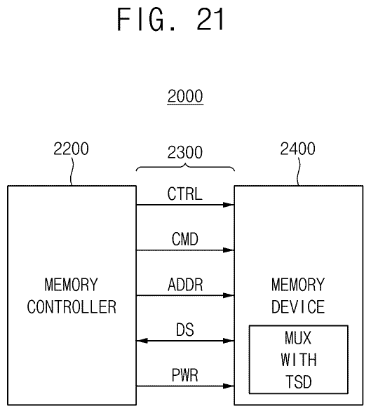

The address register 1220 may receive the address ADDR including a bank address BANK_ADDR, a row address ROW_ADDR, and a column address COL_ADDR from a memory controller (e.g., a memory controller 2200 in FIG. 21). The address register 1220 may provide the received bank address BANK_ADDR to the bank control logic circuit 1230, may provide the received row address ROW_ADDR to the row address multiplexer 1240, and may provide the received column address COL_ADDR to the column address latch 1250.

The bank control logic circuit 1230 may generate bank control signals in response to the bank address BANK_ADDR. One of the first to eighth bank row decoders 1260a to 1260h corresponding to the bank address BANK_ADDR may be activated in response to the bank control signals, and one of the first to eighth bank column decoders 1270a to 1270h corresponding to the bank address BANK_ADDR may be activated in response to the bank control signals.

The row address multiplexer 1240 may receive the row address ROW_ADDR from the address register 1220, and may receive a refresh row address REF_ADDR from the refresh counter 1245. The row address multiplexer 1240 may selectively output the row address ROW_ADDR or the refresh row address REF_ADDR as a row select address RA. The row select address RA that is output from the row address multiplexer 1240 may be applied to the first to eighth bank row decoders 260a to 260h.

The activated one of the first to eighth bank row decoders 1260a to 1260h may decode the row select address RA that is output from the row address multiplexer 1240, and may activate in the corresponding bank array a wordline WL corresponding to the row select address RA. For example, the activated bank row decoder may generate a wordline driving voltage, and may apply the wordline driving voltage to the wordline WL corresponding to the row select address RA.

The column address latch 1250 may receive the column address COL_ADDR from the address register 1220, and may temporarily store the received column address COL_ADDR. In some example embodiments, in a burst mode, the column address latch 1250 may generate column addresses that increment from the received column address COL_ADDR. The column address latch 1250 may apply the temporarily stored or generated column address COL_ADDR′ to the first to eighth bank column decoders 1270a to 1270h.

The activated one of the first to eighth bank column decoders 1270a to 1270h may decode the column address COL_ADDR′ that is output from the column address latch 1250, and may control the I/O gating circuit 1290 to output data corresponding to the column address COL_ADDR′.

The I/O gating circuit 1290 may include circuitry configured to gate input/output data. The I/O gating circuit 1290 may further include read data latches configured to store data that is output from the first to eighth bank arrays 1310 to 1380, and may also include write drivers for writing data to the first to eighth bank arrays 1310 to 1380.

Data DAT read from one of the first to eighth bank arrays 1310 to 1380 may be sensed by a sense amplifier connected to the one bank array from which the data DAT is to be read, and may be stored in the read data latches. The data DAT stored in the read data latches may be provided to the memory controller via the data I/O buffer 1295. Data DAT to be written in one of the first to eighth bank arrays 1310 to 1380 may be provided to the I/O gating circuit 1290 via the data I/O buffer 1295 from the memory controller, and the I/O gating circuit 1290 may write the data DAT in the one bank array through the write drivers.

The control logic circuit 1210 may control operations of the semiconductor memory device 1200. For example, the control logic circuit 1210 may generate control signals for the semiconductor memory device 1200 to perform the write operation and/or the read operation. The control logic circuit 1210 may include a command decoder 1211 that decodes a command CMD received from the memory controller, and a mode register 1212 that sets an operation mode of the semiconductor memory device 1200. In some example embodiments, operations described herein as being performed by the control logic circuit 1210 may be performed by processing circuitry. For example, the command decoder 1211 may generate the control signals corresponding to the command CMD by decoding a write enable signal, a row address strobe signal, a column address strobe signal, a chip selection signal, etc.

The semiconductor memory device 1200 may be the semiconductor memory device according to example embodiments described above with reference to FIGS. 1 through 19. For example, the memory cell array 1300 may have a structure in which adjacent memory cells share the local bitline. In addition, the structures at the uppermost level of the memory cell array 1300 may be used as the local bitline multiplexer. Further, two control contacts for signal application may be disposed at both ends of the control line that is connected to the local bitline multiplexer. Accordingly, the semiconductor memory device 1200 may have improved electrical characteristics and improved reliability. The sense amplifiers SA1 and SA2 in FIG. 16 may be included in the sense amplifier unit 1285.

FIG. 21 is a block diagram illustrating a memory system according to example embodiments.

Referring to FIG. 21, a memory system 2000 includes a memory controller 2200 and a semiconductor memory device 2400. The memory system 2000 may further include a plurality of signal lines 2300 that electrically connect the memory controller 2200 to the semiconductor memory device 2400.

The semiconductor memory device 2400 is controlled by the memory controller 2200. For example, based on requests from a host (not shown), the memory controller 2200 may store (e.g., write or program) data into the semiconductor memory device 2400, or may retrieve (e.g., read or sense) data from the semiconductor memory device 2400. The semiconductor memory device 2400 may be the memory device previously described. For example, in the semiconductor memory device 2400, adjacent memory cells may share the local bitline, the structures at the uppermost level of the memory cell array may be used as the local bitline multiplexer, and the two side driving (TSD) scheme in which two control contacts for signal application are disposed at both ends of the control line that is connected to the local bitline multiplexer may be implemented. Accordingly, the semiconductor memory device 2400 may have improved electrical characteristics and improved reliability.

The plurality of signal lines 2300 may include control lines, command lines, address lines, data input/output (I/O) lines and power lines. The memory controller 2200 may transmit a command CMD, an address ADDR and a control signal CTRL to the semiconductor memory device 2400 via the command lines, the address lines and the control lines, may exchange a data signal DS with the semiconductor memory device 2400 via the data I/O lines, and may transmit a power supply voltage PWR to the semiconductor memory device 2400 via the power lines. Although not illustrated in detail, the plurality of signal lines 2300 may further include data strobe signal (DQS) lines for transmitting a DQS signal.

The example embodiments may be applied to various electronic devices and systems that include the semiconductor memory devices. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

While the invention has been particularly shown and described with reference to embodiments thereof, it will be understood that various changes in form and details may be made therein without departing from the spirit and scope of the present invention as set forth in the following claims.

What is claimed is:

1. A semiconductor memory device comprising:
a plurality of memory cells on a substrate, the plurality of memory cells being arranged along a first direction, a second direction and a third direction, the first direction being perpendicular to an upper surface of the substrate, the second and third directions being parallel to the upper surface of the substrate and intersecting each other;
a plurality of local bitlines on the substrate, the plurality of local bitlines being connected to the plurality of memory cells, each of the plurality of local bitlines extending in the first direction, each of the plurality of local bitlines being shared by memory cells adjacent to a first side of each of the plurality of local bitlines and memory cells adjacent to a second side of each of the plurality of local bitlines;
a plurality of global bitlines on the plurality of local bitlines;
a plurality of wordlines on the substrate, the plurality of wordlines being connected to the plurality of memory cells, each of the plurality of wordlines extending in the third direction;
a plurality of control lines on the plurality of wordlines, each of the plurality of control lines extending in the third direction;
a plurality of local bitline multiplexers configured to control electrical connections between the plurality of local bitlines and the plurality of global bitlines, at least two of the plurality of local bitline multiplexers sharing one of the plurality of control lines;
a plurality of first control contacts connected to first ends of the plurality of control lines, each of the plurality of first control contacts extending in the first direction; and
a plurality of second control contacts connected to second ends of the plurality of control lines, each of the plurality of second control contacts extending in the first direction.

2. The semiconductor memory device of claim 1,
wherein the plurality of local bitlines include a first local bitline,
wherein the plurality of memory cells include first memory cells that are connected to the first local bitline and arranged along the first direction to be adjacent to the first side of the first local bitline,
wherein the plurality of wordlines include first wordlines that are arranged along the first direction and connected to the first memory cells, and
wherein the plurality of control lines include a first control line on the first wordlines.

3. The semiconductor memory device of claim 2,
wherein the plurality of first control contacts include a third control contact that is connected to a first end of the first control line, and
wherein the plurality of second control contacts include a fourth control contact that is connected to a second end of the first control line.

4. The semiconductor memory device of claim 2,
wherein the plurality of global bitlines include a first global bitline, and
wherein the plurality of local bitline multiplexers include a first local bitline multiplexer connected to the first control line and configured to control an electrical connection between the first local bitline and the first global bitline.

5. The semiconductor memory device of claim 4, wherein the first local bitline multiplexer includes:
a first transistor connected between the first local bitline and the first global bitline, the first transistor having a gate electrode connected to the first control line.

6. The semiconductor memory device of claim 5, wherein the first local bitline multiplexer further includes:
a second transistor connected between the first local bitline and a precharge voltage.

7. The semiconductor memory device of claim 6, wherein the plurality of control lines further include:
a second control line connected to a gate electrode of the second transistor.

8. The semiconductor memory device of claim 7, wherein the plurality of first control contacts include:
a fifth control contact connected to a first end of the second control line.

9. The semiconductor memory device of claim 8, wherein the plurality of second control contacts include:
a sixth control contact connected to a second end of the second control line.

10. The semiconductor memory device of claim 7,
wherein the plurality of memory cells further include second memory cells that are connected to the first local bitline and arranged along the first direction to be adjacent to the second side of the first local bitline,
wherein the plurality of wordlines further include second wordlines that are arranged along and spaced apart from each other in the first direction and connected to the second memory cells, and
wherein the second control line is on the second wordlines.

11. The semiconductor memory device of claim 1, further comprising:
a plurality of wordline contacts connected to the plurality of wordlines, each of the plurality of wordline contacts extending in the first direction.

12. The semiconductor memory device of claim 11, wherein the plurality of wordline contacts include:
first wordline contacts connected to first ends of the plurality of wordlines; and
second wordline contacts connected to second ends of the plurality of wordlines.

13. The semiconductor memory device of claim 12,
wherein the first wordline contacts are connected to wordlines at odd-numbered levels among the plurality of wordlines, and
wherein the second wordline contacts are connected to wordlines at even-numbered levels among the plurality of wordlines.

14. A semiconductor memory device comprising:
local bitlines on a substrate, each of the local bitlines extending in a first direction perpendicular to an upper surface of the substrate, the local bitlines being spaced apart from each other in a third direction among a second direction and the third direction, the second and third directions being parallel to the upper surface of the substrate and intersecting each other;
first memory cells on the substrate, the first memory cells being connected to the local bitlines, the first memory cells being arranged along the first and third directions to be adjacent to first sides of the local bitlines;
second memory cells on the substrate, the second memory cells being connected to the local bitlines, the second memory cells being arranged along the first and third directions to be adjacent to second sides of the local bitlines;
first wordlines on the substrate, the first wordlines being arranged along the first direction, each of the first wordlines extending in the third direction, each of the first wordlines being connected to memory cells at the same level among the first memory cells;
second wordlines on the substrate, the second wordlines being arranged along the first direction, each of the second wordlines extending in the third direction, each of the second wordlines being connected to memory cells at the same level among the second memory cells;
global bitlines, each of the global bitlines being selectively connected to one of the local bitlines;
a first control line on the first wordlines, the first control line extending in the third direction;
selection transistors configured to control electrical connections between the local bitlines and the global bitlines, the first control line being shared by the selection transistors; and
a first control contact and a second control contact connected to a first end and a second end of the first control line, respectively, each of the first and second control contacts extending in the first direction.

15. The semiconductor memory device of claim 14, further comprising:
a second control line on the second wordlines, the second control line extending in the third direction; and
keeper transistors connected between the local bitlines and a precharge voltage, the second control line being shared by the keeper transistors.

16. The semiconductor memory device of claim 15, further comprising:
a third control contact connected to a first end of the second control line.

17. The semiconductor memory device of claim 16, further comprising:
a fourth control contact connected to a second end of the second control line.

18. The semiconductor memory device of claim 14, further comprising:
a plurality of wordline contacts connected to the first and second wordlines, each of the plurality of wordline contacts extending in the first direction.

19. The semiconductor memory device of claim 18, wherein the plurality of wordline contacts include:
first wordline contacts connected to first ends of wordlines at odd-numbered levels among the first and second wordlines; and
second wordline contacts connected to second ends of wordlines at even-numbered levels among the first and second wordlines.

20. A memory system comprising:
a memory controller; and
a semiconductor memory device configured to be controlled by the memory controller, the semiconductor memory device including:
a plurality of memory cells on a substrate, the plurality of memory cells being arranged along a first direction, a second direction and a third direction, the first direction being perpendicular to an upper surface of the substrate, the second and third directions being parallel to the upper surface of the substrate and intersecting each other;
a plurality of local bitlines on the substrate, the plurality of local bitlines being connected to the plurality of memory cells, each of the plurality of local bitlines extending in the first direction, each of the plurality of local bitlines being shared by memory cells adjacent to a first side of each of the plurality of local bitlines and memory cells adjacent to a second side of each of the plurality of local bitlines;
a plurality of global bitlines on the plurality of local bitlines;
a plurality of wordlines on the substrate, the plurality of wordlines being connected to the plurality of memory cells, each of the plurality of wordlines extending in the third direction;
a plurality of control lines on the plurality of wordlines, each of the plurality of control lines extending in the third direction;
a plurality of local bitline multiplexers configured to control electrical connections between the plurality of local bitlines and the plurality of global bitlines, at least two of the plurality of local bitline multiplexers sharing one of the plurality of control lines;
a plurality of first control contacts connected to first ends of the plurality of control lines, each of the plurality of first control contacts extending in the first direction; and
a plurality of second control contacts connected to second ends of the plurality of control lines, each of the plurality of second control contacts extending in the first direction.
